(19) United States
(12) Patent Application Publication
(10) Pub. No.: US 2024/0047463 A1
(43) Pub. Date: Feb. 8, 2024

(54) SEMICONDUCTOR DEVICE

(71) Applicant: SAMSUNG ELECTRONICS CO., LTD., Suwon-si (KR)

(72) Inventors: Dong Hoon HWANG, Suwon-si (KR); Seung Min SONG, Suwon-si (KR); Min Chan GWAK, Suwon-si (KR)

(73) Assignee: SAMSUNG ELECTRONICS CO., LTD., Suwon-si (KR)

(21) Appl. No.: 18/131,548

(22) Filed: Apr. 6, 2023

(30) Foreign Application Priority Data
Aug. 8, 2022 (KR) 10-2022-0098319

(51) Int. Cl. H01L 27/12; H01L 21/84

(52) U.S. Cl. CPC H01L 27/1207; H01L 21/84; H01L 21/823481

(57) ABSTRACT

In some embodiments, a semiconductor device includes a first active pattern extended in a first horizontal direction on a substrate, a second active pattern extended in the first horizontal direction on the substrate, a first bottom gate electrode extended in a second horizontal direction on the first active pattern, a first upper gate electrode extended in the second horizontal direction on the first bottom gate electrode, a second bottom gate electrode extended in the second horizontal direction on the second active pattern, a second upper gate electrode extended in the second horizontal direction on the second bottom gate electrode, and a first gate cut comprising a first portion isolating the first bottom gate electrode from the second bottom gate electrode and a second portion isolating the first upper gate electrode from the second upper gate electrode. A width of the second portion exceeds a width of the first portion.

### CROSS-REFERENCE TO RELATED APPLICATION

This application claims benefit of priority under 35 U.S.C. § 119 to Korean Patent Application No. 10-2022-0098319, filed on Aug. 8, 2022, in the Korean Intellectual Property Office, the disclosure of which is incorporated by reference herein in its entirety.

### BACKGROUND

### 1. Field

The present disclosure relates generally to a semiconductor device, and more particularly, to a semiconductor device including a multi-bridge channel field effect transistor (MBCFET™).

### 2. Description of Related Art

A multi-channel transistor including a plurality of silicon bodies in a fin and/or nano-wire shape on a substrate and forming a gate on a surface of the silicon body has been suggested as a scaling technique for increasing the density of a semiconductor device.

Such a multi-channel transistor may use a three-dimensional channel structure, which may facilitate scaling of the multi-channel transistor. Alternatively or additionally, even if a gate length of the multi-channel transistor is not increased, a current control capability of the multi-channel transistor may be improved. Furthermore, a short channel effect (SCE) in which a potential of a channel region is affected by a drain voltage may be suppressed.

### SUMMARY

The present disclosure may provide a semiconductor device in which a width of a portion of a gate cut for isolating upper gate electrodes is greater than that of another portion of the gate cut for isolating bottom gate electrodes in a structure in which the upper gate electrodes are stacked on the bottom gate electrodes. For that reason, through vias connected to bottom source/drain contacts may be formed that do not to overlap the upper gate electrodes in a horizontal direction, and, as a result, a short may be prevented from occurring between the upper gate electrodes and the through vias.

According to an aspect of the present disclosure, a semiconductor device is provided. The semiconductor device includes a first active pattern extended in a first horizontal direction on a substrate. The semiconductor device further includes a second active pattern extended in the first horizontal direction on the substrate. The second active pattern is spaced apart from the first active pattern in a second horizontal direction different from the first horizontal direction. The semiconductor device further includes a first bottom gate electrode extended in the second horizontal direction on the first active pattern. The semiconductor device further includes a first upper gate electrode extended in the second horizontal direction on the first bottom gate electrode. The first upper gate electrode is spaced apart from the first bottom gate electrode in a vertical direction. The semiconductor device further includes a second bottom gate electrode extended in the second horizontal direction on the second active pattern. The second bottom gate electrode is spaced apart from the first bottom gate electrode in the second horizontal direction. The semiconductor device further includes a second upper gate electrode extended in the second horizontal direction on the second bottom gate electrode. The second upper gate electrode is spaced apart from the second bottom gate electrode in the vertical direction. The second upper gate electrode is spaced apart from the first upper gate electrode in the second horizontal direction. The semiconductor device further includes a first gate cut comprising a first portion isolating the first bottom gate electrode from the second bottom gate electrode and a second portion isolating the first upper gate electrode from the second upper gate electrode. A width in the second horizontal direction of the second portion of the first gate cut exceeds a width in the second horizontal direction of the first portion of the first gate cut. The second portion of the first gate cut overlaps at least one of the first bottom gate electrode and the second bottom gate electrode in the vertical direction.

According to an aspect of the present disclosure, a semiconductor device is provided. The semiconductor device includes a first active pattern extended in a first horizontal direction on a substrate. The semiconductor device further includes a second active pattern extended in the first horizontal direction on the substrate. The second active pattern is spaced apart from the first active pattern in a second horizontal direction different from the first horizontal direction. The semiconductor device further includes a first bottom gate electrode extended in the second horizontal direction on the first active pattern. The semiconductor device further includes a first upper gate electrode extended in the second horizontal direction on the first bottom gate electrode. The first upper gate electrode is spaced apart from the first bottom gate electrode in a vertical direction. The semiconductor device further includes a second bottom gate electrode extended in the second horizontal direction on the second active pattern. The second bottom gate electrode is spaced apart from the first bottom gate electrode in the second horizontal direction. The semiconductor device further includes a second upper gate electrode extended in the second horizontal direction on the second bottom gate electrode. The second upper gate electrode is spaced apart from the second bottom gate electrode in the vertical direction. The second upper gate electrode is spaced apart from the first upper gate electrode in the second horizontal direction. The semiconductor device further includes a first bottom source/drain region disposed on one side of the first bottom gate electrode on the first active pattern. The semiconductor device further includes an interlayer insulating layer configured to cover the first bottom source/drain region. The semiconductor device further includes a first bottom source/drain contact disposed inside the interlayer insulating layer and coupled to the first bottom source/drain region. The semiconductor device further includes a first through via coupled to the first bottom source/drain contact by passing through the interlayer insulating layer in the vertical direction. The first through via is non-overlapped with the first upper gate electrode in the first horizontal direction. A pitch in the second horizontal direction between the first upper gate electrode and the second upper gate electrode exceeds a pitch in the second horizontal direction between the first bottom gate electrode and the second bottom gate electrode.

According to an aspect of the present disclosure, a semiconductor device is provided. The semiconductor device includes a first active pattern extended in a first horizontal direction on a substrate. The semiconductor device further includes a second active pattern extended in the first horizontal direction on the substrate. The second active pattern is spaced apart from the first active pattern in a second horizontal direction different from the first horizontal direction. The semiconductor device further includes a plurality of first bottom nanosheets stacked spaced apart from each other in a vertical direction on the first active pattern. The semiconductor device further includes a plurality of first upper nanosheets stacked spaced apart from each other in the vertical direction on the plurality of first bottom nanosheets. The semiconductor device further includes a plurality of second bottom nanosheets stacked spaced apart from each other in the vertical direction on the second active pattern. The semiconductor device further includes a plurality of second upper nanosheets stacked spaced apart from each other in the vertical direction on the plurality of second bottom nanosheets. The semiconductor device further includes a first bottom gate electrode extended in the second horizontal direction on the first active pattern. The first bottom gate electrode surrounds the plurality of first bottom nanosheets. The semiconductor device further includes a first upper gate electrode extended in the second horizontal direction on the first bottom gate electrode. The first upper gate electrode is spaced apart from the first bottom gate electrode in the vertical direction. The first upper gate electrode surrounds the plurality of first upper nanosheets. The semiconductor device further includes a second bottom gate electrode extended in the second horizontal direction on the second active pattern. The second bottom gate electrode is spaced apart from the first bottom gate electrode in the second horizontal direction. The second bottom gate electrode surrounds the plurality of second bottom nanosheets. The semiconductor device further includes a second upper gate electrode extended in the second horizontal direction on the second bottom gate electrode. The second upper gate electrode is spaced apart from the second bottom gate electrode in the vertical direction. The second upper gate electrode is spaced apart from the first upper gate electrode in the second horizontal direction. The second upper gate electrode surrounds the plurality of second upper nanosheets. The semiconductor device further includes a gate cut including a first portion isolating the first bottom gate electrode from the second bottom gate electrode and a second portion isolating the first upper gate electrode from the second upper gate electrode. The semiconductor device further includes a bottom source/drain region disposed on one side of the first bottom gate electrode on the first active pattern. The semiconductor device further includes an interlayer insulating layer configured to cover the bottom source/drain region. The semiconductor device further includes a bottom source/drain contact disposed inside the interlayer insulating layer and coupled to the bottom source/drain region. The semiconductor device further includes a through via coupled to the bottom source/drain contact by passing through the interlayer insulating layer in the vertical direction. The through via being overlapped with the second portion of the gate cut in the first horizontal direction. A width in the second horizontal direction of the second portion of the gate cut exceeds a width in the second horizontal direction of the first portion of the gate cut.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF DRAWINGS

The above and other aspects and features of the present disclosure will become more apparent by describing in detail exemplary embodiments thereof with reference to the attached drawings, in which:

FIG. 1 is a layout view illustrating a semiconductor device, according to some embodiments of the present disclosure;

FIG. 2 is a layout view illustrating a bottom structure of a semiconductor device shown in FIG. 1, according to some embodiments of the present disclosure;

FIG. 3 is a layout view illustrating an upper structure of a semiconductor device shown in FIG. 1, according to some embodiments of the present disclosure;

FIG. 4 is a cross-sectional view taken along line A-A′ of each of FIGS. 1 to 3, according to some embodiments of the present disclosure;

FIG. 5 is a cross-sectional view taken along line B-B′ of each of FIGS. 1 to 3, according to some embodiments of the present disclosure;

FIG. 6 is a cross-sectional view taken along line C-C′ of each of FIGS. 1 to 3, according to some embodiments of the present disclosure;

FIG. 7 is a cross-sectional view taken along line D-D′ of each of FIGS. 1 to 3, according to some embodiments of the present disclosure;

FIG. 8 is a cross-sectional view taken along line E-E′ of each of FIGS. 1 to 3, according to some embodiments of the present disclosure;

FIGS. 9 to 41 are views illustrating intermediate steps to describe a method of manufacturing a semiconductor device, according to some embodiments of the present disclosure;

FIG. 42 is a cross-sectional view illustrating a semiconductor device, according to some other embodiments of the present disclosure;

FIG. 43 is a cross-sectional view illustrating a semiconductor device, according to some other embodiments of the present disclosure;

FIG. 44 is a cross-sectional view illustrating a semiconductor device, according to some other embodiments of the present disclosure;

FIG. 45 is a cross-sectional view illustrating a semiconductor device, according to some other embodiments of the present disclosure;

FIG. 46 is a layout view illustrating a semiconductor device, according to some other embodiments of the present disclosure;

FIG. 47 is a layout view illustrating a bottom structure of a semiconductor device, according to some other embodiments of the present disclosure;

FIG. 48 is a layout view illustrating an upper structure of a semiconductor device, according to some other embodiments of the present disclosure;

FIG. 49 is a cross-sectional view taken along line F-F′ of each of FIGS. 46 to 48, according to some embodiments of the present disclosure; and

FIG. 50 is a cross-sectional view taken along line G-G′ of each of FIGS. 46 to 48, according to some embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art will recognize that various changes and modifications of the embodiments described herein can be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, etc. may be replaced with terms, such as “first,” “second,” third” to be used to describe relative positions of elements. The terms “first,” “second,” third” may be used to described various elements but the elements are not limited by the terms and a “first element” may be referred to as a “second element”. Alternatively or additionally, the terms “first”, “second”, “third”, etc. may be used to distinguish components from each other and do not limit the present disclosure. For example, the terms “first”, “second”, “third”, etc. may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

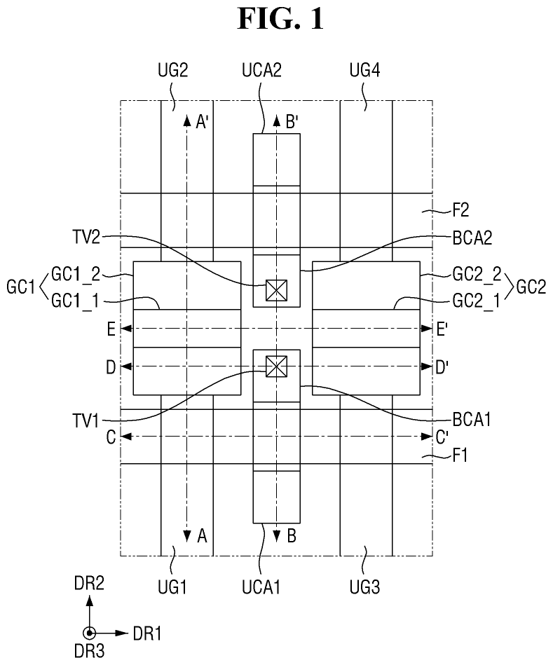

Hereinafter, a semiconductor device, according to some embodiments of the present disclosure, is described with reference to FIGS. 1 to 8.

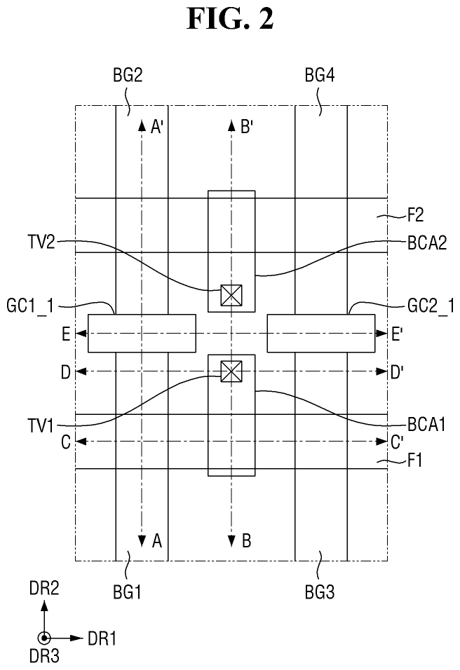

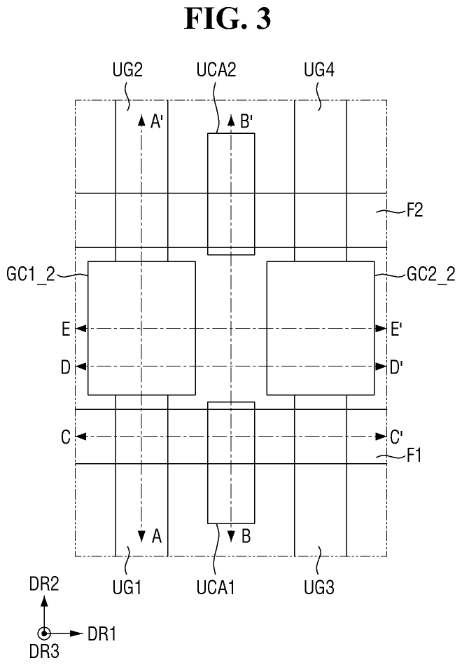

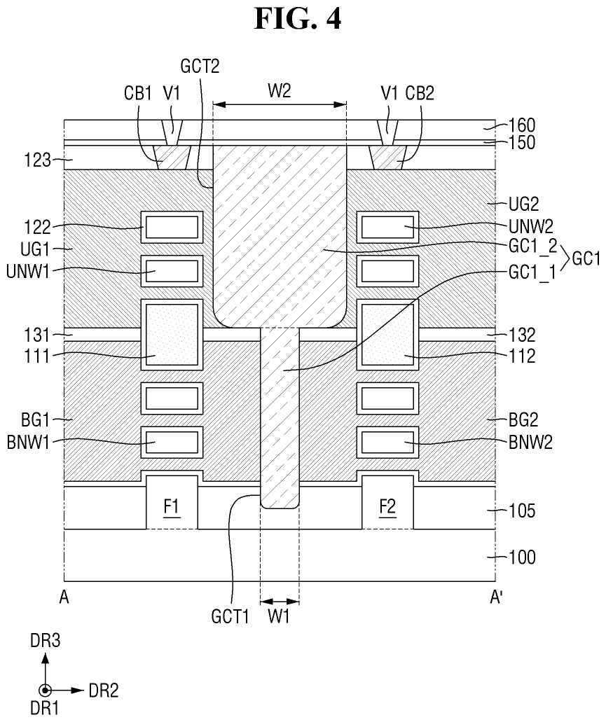

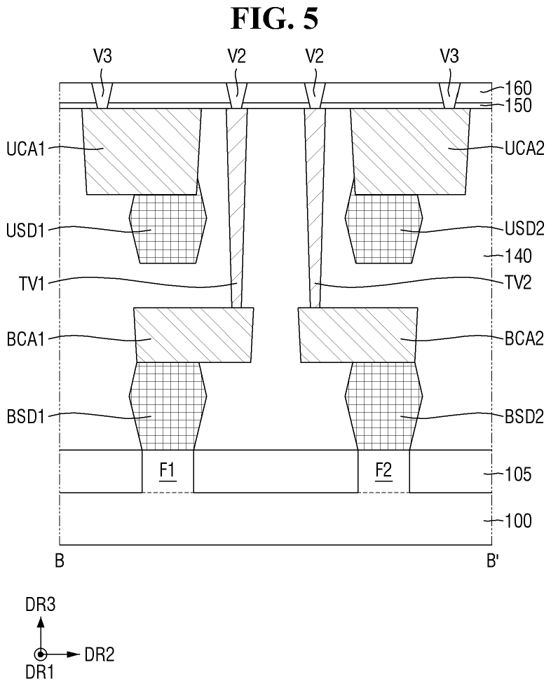

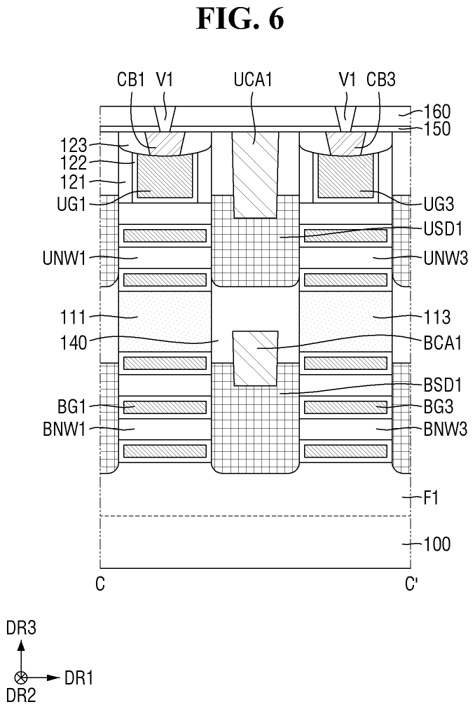

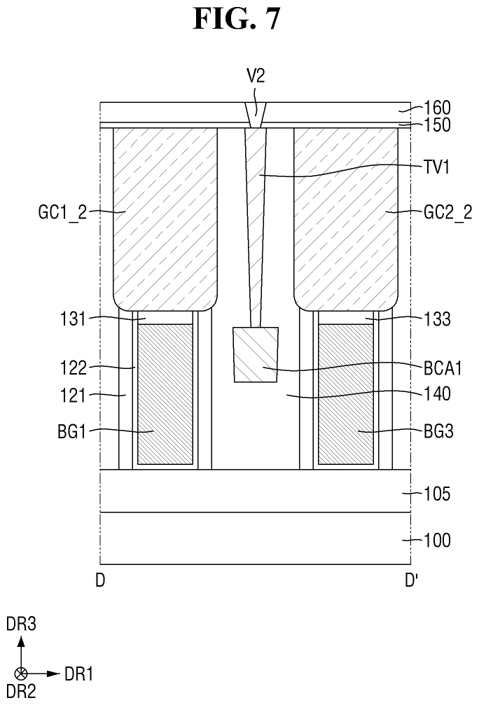

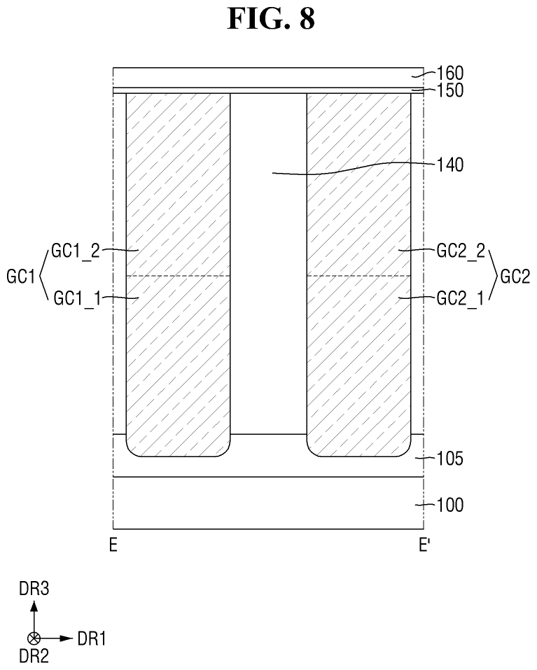

FIG. 1 is a layout view illustrating a semiconductor device, according to some embodiments of the present disclosure. FIG. 2 is a layout view illustrating a bottom structure of a semiconductor device shown in FIG. 1. FIG. 3 is a layout view illustrating an upper structure of a semiconductor device shown in FIG. 1. FIG. 4 is a cross-sectional view taken along line A-A′ of each of FIGS. 1 to 3. FIG. 5 is a cross-sectional view taken along line B-B′of each of FIGS. 1 to 3. FIG. 6 is a cross-sectional view taken along line C-C′ of each of FIGS. 1 to 3. FIG. 7 is a cross-sectional view taken along line D-D′ of each of FIGS. 1 to 3. FIG. 8 is a cross-sectional view taken along line E-E′ of each of FIGS. 1 to 3.

Referring to FIGS. 1 to 8, the semiconductor device, according to some embodiments of the present disclosure, may include a substrate 100, first and second active patterns F1 and F2, a field insulating layer 105, a plurality of first to third bottom nanosheets (e.g., BNW1, BNW2 and BNW3, respectively), a plurality of first to third upper nanosheets (e.g., UNW1, UNW2 and UNW3, respectively), first to third isolation layers (e.g., 111, 112 and 113, respectively), first to fourth bottom gate electrodes (e.g., BG1 to BG4, respectively), first to fourth upper gate electrodes (e.g., UG1 to UG4, respectively), a gate spacer 121, a gate insulating layer 122, a capping pattern 123, first to third gate isolation layers (e.g., 131, 132 and 133, respectively), first and second gate cuts (e.g., GC1 and GC2, respectively), first and second bottom source/drain regions (e.g., BSD1 and BSD2, respectively), first and second upper source/drain regions (e.g., USD1 and USD2, respectively), a first interlayer insulating layer 140, first and second bottom source/drain contacts (e.g., BCA1 and BCA2, respectively), first and second upper source/drain contacts (e.g., UCA1 and UCA2, respectively), first to third gate contacts (e.g., CB1, CB2 and CB3, respectively), first and second through vias (e.g., TV1 and TV2, respectively), an etch stop layer 150, a second interlayer insulating layer 160, and first to third vias (e.g., V1, V2 and V3, respectively).

The substrate 100 may be a silicon substrate or a silicon-on-insulator (SOI). Alternatively or additionally, the substrate 100 may include, but not be limited to, silicon germanium (SiGe), silicon germanium on insulator (SGOI), indium antimonide (InSb), lead telluride compound (PbTe), indium arsenide (InAs), indium phosphide (InP), gallium arsenide (GaAs), or gallium antimonide (GaSb). That is, the present disclosure is not limited in this regard.

Hereinafter, each of a first horizontal direction DR1 and a second horizontal direction DR2 may refer to directions that are parallel with an upper surface of the substrate 100. The second horizontal direction DR2 may refer to as a direction different from the first horizontal direction DR1. A vertical direction DR3 may refer to a direction perpendicular to each of the first horizontal direction DR1 and the second horizontal direction DR2.

Each of the first active pattern F1 and the second active pattern F2 may be protruded from the substrate 100 in the vertical direction DR3. Each of the first active pattern F1 and the second active pattern F2 may be extended in the first horizontal direction DR1 on the substrate 100. The second active pattern F2 may be spaced apart from the first active pattern F1 in the second horizontal direction DR2. Each of the first active pattern F1 and the second active pattern F2 may be a portion of the substrate 100, and/or may include an epitaxial layer grown from the substrate 100.

The field insulating layer 105 may be disposed on the substrate 100. The field insulating layer 105 may surround sidewalls of each of the first active pattern F1 and the second active pattern F2. For example, an upper surface of each of the first active pattern F1 and the second active pattern F2 may be more protruded in the vertical direction DR3 than that of the field insulating layer 105. However, the present disclosure is not limited in this regard. For example, in some embodiments, the upper surface of each of the first active pattern F1 and the second active pattern F2 may be formed on the same plane as that of the field insulating layer 105.

The plurality of first bottom nanosheets BNW1 may be disposed on the first active pattern F1. The plurality of first bottom nanosheets BNW1 may include a plurality of nanosheets stacked to be spaced apart from each other in the vertical direction DR3 on the first active pattern F1. The plurality of first bottom nanosheets BNW1 may be disposed at a portion where the first active pattern F1 and the first bottom gate electrode BG1 cross each other.

The plurality of second bottom nanosheets BNW2 may be disposed on the second active pattern F2. The plurality of second bottom nanosheets BNW2 may include a plurality of nanosheets stacked to be spaced apart from each other in the vertical direction DR3 on the second active pattern F2. The plurality of second bottom nanosheets BNW2 may be disposed at a portion where the second active pattern F2 and the second bottom gate electrode BG2 cross each other.

The plurality of third bottom nanosheets BNW3 may be disposed on the first active pattern F1. The plurality of third bottom nanosheets BNW3 may include a plurality of nanosheets stacked to be spaced apart from each other in the vertical direction DR3 on the first active pattern F1. The plurality of third bottom nanosheets BNW3 may be disposed at a portion where the first active pattern F1 and the third bottom gate electrode BG3 cross each other.

In some embodiments, a plurality of fourth bottom nanosheets may be disposed on the second active pattern F2 (not shown). The plurality of fourth bottom nanosheets may include a plurality of nanosheets stacked to be spaced apart from each other in the vertical direction DR3 on the second active pattern F2. The plurality of fourth bottom nanosheets may be disposed at a portion where the second active pattern F2 and the fourth bottom gate electrode BG4 cross each other.

Although FIGS. 4 and 6 show that each of the plurality of first to third bottom nanosheets (e.g., BNW1, BNW2 and BNW3) includes two nanosheets stacked in the vertical direction DR3, this is for convenience of description. For example, in some embodiments, each of the plurality of first to third bottom nanosheets (e.g., BNW1, BNW2 and BNW3) may include three or more nanosheets stacked in the vertical direction DR3.

The plurality of first upper nanosheets UNW1 may be disposed on the plurality of first bottom nanosheets BNW1. The plurality of first upper nanosheets UNW1 may include a plurality of nanosheets stacked to be spaced apart from each other in the vertical direction DR3 on the plurality of first bottom nanosheets BNW1. The plurality of first upper nanosheets UNW1 may be disposed at a portion where the first active pattern F1 and the first upper gate electrode UG1 cross each other.

The plurality of second upper nanosheets UNW2 may be disposed on the plurality of second bottom nanosheets BNW2. The plurality of second upper nanosheets UNW2 may include a plurality of nanosheets stacked to be spaced apart from each other in the vertical direction DR3 on the plurality of second bottom nanosheets BNW2. The plurality of second upper nanosheets UNW2 may be disposed at a portion where the second active pattern F2 and the second upper gate electrode UG2 cross each other.

The plurality of third upper nanosheets UNW3 may be disposed on the plurality of third bottom nanosheets BNW3. The plurality of third upper nanosheets UNW3 may include a plurality of nanosheets stacked to be spaced apart from each other in the vertical direction DR3 on the plurality of third bottom nanosheets BNW1. The plurality of third upper nanosheets UNW3 may be disposed at a portion where the first active pattern F1 and the third upper gate electrode UG3 cross each other.

In some embodiments, a plurality of fourth upper nanosheets may be disposed on the plurality of fourth bottom nanosheets (not shown). The plurality of fourth upper nanosheets may include a plurality of nanosheets stacked to be spaced apart from each other in the vertical direction DR3 on the plurality of fourth bottom nanosheets. The plurality of fourth upper nanosheets may be disposed at a portion where the second active pattern F2 and the fourth upper gate electrode UG4 cross each other.

Although FIGS. 4 and 6 show that each of the first to plurality of third upper nanosheets (e.g., UNW1, UNW2 and UNW3) includes two nanosheets stacked in the vertical direction DR3, this is for convenience of description. For example, in some embodiments, each of the first to plurality of third upper nanosheets UNW1, UNW2 and UNW3 may include three or more nanosheets stacked in the vertical direction DR3.

The first isolation layer 111 may be disposed between the plurality of first bottom nanosheets BNW1 and the plurality of first upper nanosheets UNW1. For example, the first isolation layer 111 may be spaced apart from each of the plurality of first bottom nanosheets BNW1 and the plurality of first upper nanosheets UNW1 in the vertical direction DR3. However, the present disclosure is not limited in this regard.

The second isolation layer 112 may be disposed between the plurality of second bottom nanosheets BNW2 and the plurality of second upper nanosheets UNW2. For example, the second isolation layer 112 may be spaced apart from each of the plurality of second bottom nanosheets BNW2 and the plurality of second upper nanosheets UNW2 in the vertical direction DR3. However, the present disclosure is not limited in this regard.

The third isolation layer 113 may be disposed between the plurality of third bottom nanosheets BNW3 and the plurality of third upper nanosheets UNW3. For example, the third isolation layer 113 may be spaced apart from each of the plurality of third bottom nanosheets BNW3 and the plurality of third upper nanosheets UNW3 in the vertical direction DR3. However, the present disclosure is not limited in this regard.

In some embodiments, a fourth isolation layer may be disposed between the plurality of fourth bottom nanosheets and the plurality of fourth upper nanosheets (not shown). For example, the fourth isolation layer may be spaced apart from each of the plurality of fourth bottom nanosheets and the plurality of fourth upper nanosheets in the vertical direction DR3. However, the present disclosure is not limited in this regard.

Each of the first to third isolation layers 111, 112 and 113 may include an insulating material. For example, each of the first to third isolation layers (e.g., 111, 112 and 113, respectively) may include at least one of silicon nitride (SiN), silicon oxycarbonitride (SiOCN), silicon boron carbonitride (SiBCN), silicon carbonitride (SiCN), silicon oxynitride (SiON), and a combination thereof. However, the present disclosure is not limited in this regard.

The first bottom gate electrode BG1 may be extended in the second horizontal direction DR2 on the first active pattern F1 and the field insulating layer 105. The first bottom gate electrode BG1 may surround the plurality of first bottom nanosheets BNW1. For example, the first bottom gate electrode BG1 may surround a portion of the first isolation layer 111. The second bottom gate electrode BG2 may be extended in the second horizontal direction DR2 on the second active pattern F2 and the field insulating layer 105. The second bottom gate electrode BG2 may be spaced apart from the first bottom gate electrode BG1 in the second horizontal direction DR2. The second bottom gate electrode BG2 may surround the plurality of second bottom nanosheets BNW2. For example, the second bottom gate electrode BG2 may surround a portion of the second isolation layer 112.

The third bottom gate electrode BG3 may be extended in the second horizontal direction DR2 on the first active pattern F1 and the field insulating layer 105. The third bottom gate electrode BG3 may be spaced apart from the first bottom gate electrode BG1 in the first horizontal direction DR1. The third bottom gate electrode BG3 may surround the plurality of third bottom nanosheets BNW3. For example, the third bottom gate electrode BG3 may surround a portion of the third isolation layer 113. The fourth bottom gate electrode BG4 may be extended in the second horizontal direction DR2 on the second active pattern F2 and the field insulating layer 105. The fourth bottom gate electrode BG4 may be spaced apart from the second bottom gate electrode BG2 in the first horizontal direction DR1. The fourth bottom gate electrode BG4 may be spaced apart from the third bottom gate electrode BG3 in the second horizontal direction DR2. In some embodiments, the fourth bottom gate electrode BG4 may surround the plurality of fourth bottom nanosheets (not shown). For example, the fourth bottom gate electrode BG4 may surround a portion of the fourth isolation layer.

The first upper gate electrode UG1 may be extended in the second horizontal direction DR2 on the first bottom gate electrode BG1. The first upper gate electrode UG1 may be spaced apart from the first bottom gate electrode BG1 in the vertical direction DR3. The first upper gate electrode UG1 may surround the plurality of first upper nanosheets UNW1. For example, the first upper gate electrode UG1 may surround another portion of the first isolation layer 111. The second upper gate electrode UG2 may be extended in the second horizontal direction DR2 on the second bottom gate electrode BG2. The second upper gate electrode UG2 may be spaced apart from the second bottom gate electrode BG2 in the vertical direction DR3. The second upper gate electrode UG2 may be spaced apart from the first upper gate electrode UG1 in the second horizontal direction DR2. The second upper gate electrode UG2 may surround the plurality of second upper nanosheets UNW2. For example, the second upper gate electrode UG2 may surround another portion of the second isolation layer 112.

The third upper gate electrode UG3 may be extended in the second horizontal direction DR2 on the third bottom gate electrode BG3. The third upper gate electrode UG3 may be spaced apart from the third bottom gate electrode BG3 in the vertical direction DR3. The third upper gate electrode UG3 may be spaced apart from the first upper gate electrode UG1 in the first horizontal direction DR1. The third upper gate electrode UG3 may surround the plurality of third upper nanosheets UNW3. For example, the third upper gate electrode UG3 may surround another portion of the third isolation layer 113. The fourth upper gate electrode UG4 may be extended in the second horizontal direction DR2 on the fourth bottom gate electrode BG4. The fourth upper gate electrode UG4 may be spaced apart from the fourth bottom gate electrode BG4 in the vertical direction DR3. The fourth upper gate electrode UG4 may be spaced apart from the second upper gate electrode UG2 in the first horizontal direction DR1. The fourth upper gate electrode UG4 may be spaced apart from the third upper gate electrode UG3 in the second horizontal direction DR2. In some embodiments, the fourth upper gate electrode UG4 may surround the plurality of fourth upper nanosheets (not shown). For example, the fourth upper gate electrode UG4 may surround another portion of the fourth isolation layer.

For example, a pitch in the second horizontal direction DR2 between the first upper gate electrode UG1 and the second upper gate electrode UG2 may be greater than a pitch in the second horizontal direction DR2 between the first bottom gate electrode BG1 and the second bottom gate electrode BG2. Alternatively or additionally, a pitch in the second horizontal direction DR2 between the third upper gate electrode UG3 and the fourth upper gate electrode UG4 may be greater than a pitch in the second horizontal direction DR2 between the third bottom gate electrode BG3 and the fourth bottom gate electrode BG4.

Each of the first to fourth bottom gate electrodes BG1 to BG4 and the first to fourth upper gate electrodes UG1 to UG4 may include, but not be limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof.

In some embodiments, the first to fourth bottom gate electrodes (e.g., BG1 to BG4, respectively) may include a material different from that of the first to fourth upper gate electrodes UG1 to UG4. However, the present disclosure is not limited in this regard. For example, in some embodiments, the first to fourth bottom gate electrodes BG1 to BG4 may include the same material as that of the first to fourth upper gate electrodes UG1 to UG4.

The first gate isolation layer 131 may be disposed between the first bottom gate electrode BG1 and the first upper gate electrode UG1. The first gate isolation layer 131 may isolate the first bottom gate electrode BG1 from the first upper gate electrode UG1. The second gate isolation layer 132 may be disposed between the second bottom gate electrode BG2 and the second upper gate electrode UG2. The second gate isolation layer 132 may isolate the second bottom gate electrode BG2 from the second upper gate electrode UG2.

The third gate isolation layer 133 may be disposed between the third bottom gate electrode BG3 and the third upper gate electrode UG3. The third gate isolation layer 133 may isolate the third bottom gate electrode BG3 from the third upper gate electrode UG3. In some embodiments, the fourth gate isolation layer may be disposed between the fourth bottom gate electrode BG4 and the fourth upper gate electrode UG4 (not shown). The fourth gate isolation layer may isolate the fourth bottom gate electrode BG4 from the fourth upper gate electrode UG4. Each of the first to third gate isolation layers 131, 132 and 133 may include, for example, a conductive material. However, the present disclosure is not limited in this regard. For example, in some embodiments, each of the first to third gate isolation layers 131, 132 and 133 may include an insulating material.

The gate spacer 121 may be extended in the second horizontal direction DR2 along both sidewalls of each of the first bottom gate electrode BG1 and the first upper gate electrode UG1 on the uppermost nanosheet of the plurality of first upper nanosheets UNW1 and the field insulating layer 105. For example, the gate spacer 121 may be disposed on both sidewalls of the first gate isolation layer 131. Alternatively or additionally, the gate spacer 121 may be extended in the second horizontal direction DR2 along both sidewalls of each of the third bottom gate electrode BG3 and the third upper gate electrode UG3 on the uppermost nanosheet of the plurality of third upper nanosheets UNW3 and the field insulating layer 105.

For example, the gate spacer 121 may be disposed on both sidewalls of the third gate isolation layer 133.

In some embodiments, the gate spacer 121 may be extended in the second horizontal direction DR2 along both sidewalls of each of the second bottom gate electrode BG2 and the second upper gate electrode UG2 on the uppermost nanosheet of the plurality of second upper nanosheets UNW2 and the field insulating layer 105 (not shown). For example, the gate spacer 121 may be disposed on both sidewalls of the second gate isolation layer 132. Alternatively or additionally, the gate spacer 121 may be extended in the second horizontal direction DR2 along both sidewalls of each of the fourth bottom gate electrode BG4 and the fourth upper gate electrode UG4 on the uppermost nanosheet of the plurality of fourth upper nanosheets and the field insulating layer 105. For example, the gate spacers 121 may be disposed on both sidewalls of the fourth gate isolation layer.

The gate spacer 121 may include, but not be limited to, at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and a combination therefore. However, the present disclosure is not limited in this regard.

The first bottom source/drain region BSD1 may be disposed on at least one side of each of the first and third bottom gate electrodes BG1 and BG3 on the first active pattern F1. For example, the first bottom source/drain region BSD1 may be disposed between the first bottom gate electrode BG1 and the third bottom gate electrode BG3 on the first active pattern F1. The first bottom source/drain region BSD1 may be in contact with each of the plurality of first bottom nanosheets BNW1 and the plurality of third bottom nanosheets BNW3. Although FIG. 6 shows that an upper surface of the first bottom source/drain region BSD1 is formed to be lower than a lower surface of the first isolation layer 111, this is for convenience of description. However, the present disclosure is not limited in this regard.

The second bottom source/drain region BSD2 may be disposed on at least one side of each of the second and fourth bottom gate electrodes BG2 and BG4 on the second active pattern F2. For example, the second bottom source/drain region BSD2 may be disposed between the second bottom gate electrode BG2 and the fourth bottom gate electrode BG4 on the second active pattern F2. The second bottom source/drain region BSD2 may be in contact with each of the plurality of second bottom nanosheets BNW2 and the plurality of fourth bottom nanosheets.

The first upper source/drain region USD1 may be disposed on at least one side of each of the first and third upper gate electrodes UG1 and UG3 on the first bottom source/drain region BSD1. For example, the first upper source/drain region USD1 may be disposed between the first upper gate electrode UG1 and the third upper gate electrode UG3 on the first bottom source/drain region BSD1. The first upper source/drain region USD1 may be spaced apart from the first bottom source/drain region BSD1 in the vertical direction DR3. For example, the first interlayer insulating layer 140 may be disposed between the first bottom source/drain region BSD1 and the first upper source/drain region USD1. The first upper source/drain region USD1 may be in contact with each of the plurality of first upper nanosheets UNW1 and the plurality of third upper nanosheets UNW3. Although FIG. 6 shows that a lower surface of the first upper source/drain region USD1 is formed to be higher than an upper surface of the first isolation layer 111, this is for convenience of description. However, the present disclosure is not limited in this regard.

The second upper source/drain region USD2 may be disposed on at least one side of each of the second and fourth upper gate electrodes UG2 and UG4 on the second bottom source/drain region BSD2. For example, the second upper source/drain region USD2 may be disposed between the second upper gate electrode UG2 and the fourth upper gate electrode UG4 on the second bottom source/drain region BSD2. The second upper source/drain region USD2 may be spaced apart from the second bottom source/drain region BSD2 in the vertical direction DR3. For example, the first interlayer insulating layer 140 may be disposed between the second bottom source/drain region BSD2 and the second upper source/drain region USD2. The second upper source/drain region USD2 may be in contact with each of the plurality of second upper nanosheets UNW2 and the plurality of fourth upper nanosheets.

The gate insulating layer 122 may be disposed between each of the first to fourth bottom gate electrodes BG1 to BG4 and the field insulating layer 105. The gate insulating layer 122 may be disposed between each of the first to fourth bottom gate electrodes BG1 to BG4 and each of the plurality of first to fourth bottom nanosheets (e.g., BNW1, BNW2 and BNW3). The gate insulating layer 122 may be disposed between each of the first to fourth bottom gate electrodes BG1 to BG4 and each of the first to fourth isolation layers 111, 112 and 113. The gate insulating layer 122 may be disposed between each of the first and third bottom gate electrodes BG1 and BG3 and the first bottom source/drain region BSD1. The gate insulating layer 122 may be disposed between each of the second and fourth bottom gate electrodes BG2 and BG4 and the second bottom source/drain region BSD2. The gate insulating layer 122 may be disposed between each of the first to fourth bottom gate electrodes BG1 to BG4 and the gate spacer 121. The gate insulating layer 122 may be disposed between each of the first to fourth isolation layers 111, 112 and 113 and each of the first to fourth gate isolation layers 131, 132 and 133.

Alternatively or additionally, the gate insulating layer 122 may be disposed between each of the first to fourth upper gate electrodes UG1 to UG4 and each of the first to fourth upper nanosheets UNW1, UNW2 and UNW3. The gate insulating layer 122 may be disposed between each of the first to fourth upper gate electrodes UG1 to UG4 and each of the first to fourth isolation layers 111, 112 and 113. The gate insulating layer 122 may be disposed between each of the first and third upper gate electrodes UG1 and UG3 and the first upper source/drain region USD1. The gate insulating layer 122 may be disposed between each of the second and fourth upper gate electrodes UG2 and UG4 and the second upper source/drain region USD2. The gate insulating layer 122 may be disposed between each of the first to fourth upper gate electrodes UG1 to UG4 and the gate spacer 121.

The gate insulating layer 122 may be in contact with each of the first bottom source/drain region BSD1, the second bottom source/drain region BSD2, the first upper source/drain region USD1 and the second upper source/drain region USD2. However, the present disclosure is not limited in this regard. For example, in some embodiments, an inner spacer may be disposed between each of the first bottom source/drain region BSD1, the second bottom source/drain region BSD2, the first upper source/drain region USD1 and the second upper source/drain region USD2 and the gate insulating layer 122.

The gate insulating layer 122 may include, but not be limited to, at least one of silicon oxide (SiO₂), silicon oxynitride (SiON), silicon nitride, or a high dielectric constant material having a dielectric constant greater than that of the silicon oxide. The high dielectric constant material may include, but not be limited to, one or more of hafnium oxide (HfO₂), hafnium silicon oxide (HfSiO₂), hafnium aluminum oxide (HfAlO₂), lanthanum oxide (La₂O₃), lanthanum aluminum oxide (AlLaO₃), zirconium oxide (ZrO₂), zirconium silicon oxide (ZrSiO₄), tantalum oxide (Ta₂O₅), titanium oxide (TiO₂), barium strontium titanium oxide (BaSrTi₂O₆), barium titanium oxide (BaO₃Ti), strontium titanium oxide (SrTiO₃), yttrium oxide (Y₂O₃), aluminum oxide (Al₂O₃), lead scandium tantalum oxide (PST), or lead zinc niobate. As used herein, each of the terms “SiO₂”, “SiON”, “HfO₂”, “HfSiO₂”, “HfAlO₂”, “La₂O₃”, “AlLaO₃”, “ZrO₂”, “ZrSiO₄”, “Ta₂O₅”, “TiO₂”, “BaSrTi₂O₆”, “BaO₃Ti”, “SrTiO₃”, “Y₂O₃”, “Al₂O₃”, and the like may refer to a material made of elements included in each of the terms and is not a chemical formula representing a stoichiometric relationship.

The semiconductor device, according to some embodiments, may include a negative capacitance (NC) field-effect transistor (FET) based on a negative capacitor. For example, the gate insulating layer 122 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series, and the capacitance of each capacitor has a positive value, the total capacitance is more reduced than the capacitance of each individual capacitor. Alternatively or additionally, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer, which are connected in series, may be increased. Based on the total capacitance value that is increased, a transistor having a ferroelectric material layer may have a subthreshold swing (SS) less than 60 mV/decade at a room temperature, for example.

The ferroelectric material layer may have ferroelectric characteristics. The ferroelectric material layer may include, but not be limited to, at least one of hafnium oxide (HfO₂), hafnium zirconium oxide (HZO), barium strontium titanium oxide (BaSrTi₂O₆), barium titanium oxide (BaO₃Ti), and lead zirconium titanium oxide. For example, the hafnium zirconium oxide may be a material doped with zirconium (Zr) in hafnium oxide. For another example, the hafnium zirconium oxide may be a compound of hafnium (Hf), zirconium (Zr), and oxygen (O).

The ferroelectric material layer may further include a doped dopant. For example, the dopant may include, but not be limited to, at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide (HfO₂), the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum approximately between 3 at % and 8 at % (atomic %). For example, a ratio of the dopant may be a ratio of aluminum to a sum of hafnium and aluminum.

When the dopant is silicon (Si), the ferroelectric material layer may include silicon approximately between 2 at % and 10 at %. When the dopant is yttrium (Y), the ferroelectric material layer may include yttrium approximately between 2 at % and 10 at %. When the dopant is gadolinium (Gd), the ferroelectric material layer may include gadolinium approximately between 1 at % and 7 at %. When the dopant is zirconium (Zr), the ferroelectric material layer may include zirconium approximately between 50 at % and 80 at %.

The paraelectric material layer may have paraelectric characteristics. The paraelectric material layer may include, but not be limited to, at least one of silicon oxide (SiO₂) and a metal oxide having a high dielectric constant. The metal oxide included in the paraelectric material layer may include, but not be limited to, at least one of hafnium oxide (HfO₂), zirconium oxide, and aluminum oxide.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide (HfO₂), a crystal structure of hafnium oxide included in the ferroelectric material layer may be different from that of hafnium oxide included in the paraelectric material layer.

The ferroelectric material layer may have a thickness having ferroelectric characteristics. The thickness of the ferroelectric material layer may be, for example, approximately between 0.5 nanometers (nm) and 10 nm. However, the present disclosure is not limited in this regard. Since a threshold thickness indicating ferroelectric characteristics may be varied depending on each ferroelectric material, the thickness of the ferroelectric material layer may be varied depending on the ferroelectric material.

For example, the gate insulating layer 142 may include one ferroelectric material layer. For another example, the gate insulating layer 142 may include a plurality of ferroelectric material layers spaced apart from each other. The gate insulating layer 142 may have a stacked layer structure in which a plurality of ferroelectric material layers and a plurality of paraelectric material layers are alternately stacked.

The capping pattern 123 may be extended in the second horizontal direction DR2 on each of the first to fourth upper gate electrodes UG1 to UG4. For example, the capping pattern 123 may be in contact with each of an uppermost surface of the gate spacer 121 and an uppermost surface of the gate insulating layer 122. However, the present disclosure is not limited in this regard. For example, in some embodiments, the capping pattern 123 may be disposed between the gate spacers 121 on each of the first to fourth upper gate electrodes UG1 to UG4. The capping pattern 123 may include, but not be limited to, at least one of silicon nitride (SiN), silicon oxynitride (SiON), silicon oxide (SiO₂), silicon carbonitride (SiCN), silicon oxycarbonitride (SiOCN), and a combination thereof.

The first interlayer insulating layer 140 may be disposed on the field insulating layer 105. The first interlayer insulating layer 140 may cover each of the first bottom source/drain region BSD1, the second bottom source/drain region BSD2, the first upper source/drain region USD1 and the second upper source/drain region USD2. The first interlayer insulating layer 140 may surround sidewalls of the gate spacer 121. For example, an upper surface of the first interlayer insulating layer 140 may be formed on the same plane as that of the capping pattern 123. However, the present disclosure is not limited in this regard.

The first interlayer insulating layer 140 may include, but not be limited to, at least one of silicon oxide (SiO₂), silicon nitride (Si₃N₄), silicon oxynitride (SiON), or a low dielectric constant material. For example, the low dielectric constant material may include, but not be limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica, and a combination thereof.

A first gate cut trench GCT1 may be formed between the first bottom gate electrode BG1 and the second bottom gate electrode BG2. Alternatively or additionally, the first gate cut trench GCT1 may be formed between the third bottom gate electrode BG3 and the fourth bottom gate electrode BG4. For example, the first gate cut trench GCT1 may be formed between the first gate isolation layer 131 and the second gate isolation layer 132. In some embodiments, the second gate cut trench GCT1 may be formed between the third gate isolation layer 133 and the fourth gate isolation layer. For example, the first gate cut trench GCT1 may be extended from an upper surface of each of the first to fourth gate isolation layers 131, 132 and 133 to the inside of the field insulating layer 105.

The first gate cut trench GCT1 may isolate the first bottom gate electrode BG1 from the second bottom gate electrode BG2 in the second horizontal direction DR2. Alternatively or additionally, the first gate cut trench GCT1 may isolate the third bottom gate electrode BG3 from the fourth bottom gate electrode BG4 in the second horizontal direction DR2. The first gate cut trench GCT1, which isolates the first bottom gate electrode BG1 from the second bottom gate electrode BG2 in the second horizontal direction DR2, may be spaced apart from the first gate cut trench GCT1, which isolates the third bottom gate electrode BG3 from the fourth bottom gate electrode BG4 in the second horizontal direction DR2, in the first horizontal direction DR1.

A second gate cut trench GCT2 may be formed between the first upper gate electrode UG1 and the second upper gate electrode UG2. Alternatively or additionally, the second gate cut trench GCT2 may be formed between the third upper gate electrode UG3 and the fourth upper gate electrode UG4. For example, the second gate cut trench GCT2 may be extended to the upper surface of each of the first to fourth gate isolation layers 131, 132 and 133 by passing through the capping pattern 123. For example, the second gate cut trench GCT2 may expose the upper surface of each of the first to fourth gate isolation layers 131, 132 and 133 disposed at both sides of the first gate cut trench GCT1 in the second horizontal direction DR2.

The second gate cut trench GCT2 may isolate the first upper gate electrode UG1 from the second upper gate electrode UG2 in the second horizontal direction DR2. Alternatively or additionally, the second gate cut trench GCT2 may isolate the third upper gate electrode UG3 from the fourth upper gate electrode UG4 in the second horizontal direction DR2. The second gate cut trench GCT2, which isolates the first upper gate electrode UG1 from the second upper gate electrode UG2 in the second horizontal direction DR2, may be spaced apart from the second gate cut trench GCT2, which isolates the third upper gate electrode UG3 from the fourth upper gate electrode UG4 in the second horizontal direction DR2, in the first horizontal direction DR1.

The second gate cut trench GCT2 may be formed on the first gate cut trench GCT1. That is, the second gate cut trench GCT2 may overlap the first gate cut trench GCT1 in the vertical direction DR3. In some embodiments, a width of the second gate cut trench GCT2 in the second horizontal direction DR2 may be greater than that of the first gate cut trench GCT1 in the second horizontal direction DR2. For example, a width of the second gate cut trench GCT2 in the first horizontal direction DR1 may be the same as that of the first gate cut trench GCT1 in the first horizontal direction DR1. However, the present disclosure is not limited in this regard.

The first gate cut GC1 may include a first portion GC1_1 and a second portion GC12 disposed on the first portion GC1_1. The first portion GC1_1 of the first gate cut GC1 may be disposed inside the first gate cut trench GCT1 formed between the first bottom gate electrode BG1 and the second bottom gate electrode BG2. The first portion GC1_1 of the first gate cut GC1 may isolate the first bottom gate electrode BG1 from the second bottom gate electrode BG2 in the second horizontal direction DR2. For example, an upper surface of the first portion GC1_1 of the first gate cut GC1 may be formed on the same plane as the upper surface of each of the first to fourth gate isolation layers 131, 132 and 133.

In some embodiments, the first portion GC1_1 of the first gate cut GC1 may be in contact with each of the first bottom gate electrode BG1 and the second bottom gate electrode BG2. However, the present disclosure is not limited in this regard. For example, in optional or additional embodiments, the gate insulating layer 122 may be disposed between the first portion GC1_1 of the first gate cut GC1 and each of the first bottom gate electrode BG1 and the second bottom gate electrode BG2. The first portion GC1_1 of the first gate cut GC1 may be in contact with sidewalls of each of the first to fourth gate isolation layers 131, 132 and 133. The first portion GC1_1 of the first gate cut GC1 may be in contact with the field insulating layer 105.

The second portion GC1_2 of the first gate cut GC1 may be disposed inside the second gate cut trench GCT2 formed between the first upper gate electrode UG1 and the second upper gate electrode UG2. The second portion GC1_2 of the first gate cut GC1 may isolate the first upper gate electrode UG1 from the second upper gate electrode UG2 in the second horizontal direction DR2. For example, an upper surface of the second portion GC1_2 of the first gate cut GC1 may be formed on the same plane as the upper surface of the capping pattern 123. However, the present disclosure is not limited in this regard.

For example, the second portion GC1_2 of the first gate cut GC1 may be in contact with each of the first upper gate electrode UG1 and the second upper gate electrode UG2. However, the present disclosure is not limited in this regard. For example, in some embodiments, the gate insulating layer 122 may be disposed between the second portion GC1_2 of the first gate cut GC1 and each of the first upper gate electrode UG1 and the second upper gate electrode UG2. The second portion GC1_2 of the first gate cut GC1 may be in contact with the upper surface of each of the first to fourth gate isolation layers 131, 132 and 133. A lower surface of the second portion GC1_2 of the first gate cut GC1 may be in contact with the upper surface of the first portion GC1_1 of the first gate cut GC1. For example, the second portion GC1_2 of the first gate cut GC1 may be spaced apart from each of the plurality of first upper nanosheets UNW1 and the plurality of second upper nanosheets UNW2 in the second horizontal direction DR2.

A width W2 of the second portion GC1_2 of the first gate cut GC1 in the second horizontal direction DR2 may be greater than a width W1 of the first portion GC1_1 of the first gate cut GC1 in the second horizontal direction DR2. For example, the second portion GC1_2 of the first gate cut GC1 may be disposed on the first bottom gate electrode BG1 on one sidewall of the first portion GC1_1 of the first gate cut GC1 in the second horizontal direction DR2. Alternatively or additionally, the second portion GC1_2 of the first gate cut GC1 may be disposed on the second bottom gate electrode BG2 on the other sidewall of the first portion GC1_1 of the first gate cut GC1 in the second horizontal direction DR2. That is, at least a portion of the second portion GC1_2 of the first gate cut GC1 may overlap each of the first bottom gate electrode BG1 and the second bottom gate electrode BG2 in the vertical direction DR3.

The second gate cut GC2 may be spaced apart from the first gate cut GC1 in the first horizontal direction DR1. The second gate cut GC2 may include a first portion GC2_1 and a second portion GC2_2 disposed on the first portion GC2_1. The first portion GC2_1 of the second gate cut GC2 may be disposed inside the first gate cut trench GCT1 formed between the third bottom gate electrode BG3 and the fourth bottom gate electrode BG4. The first portion GC2_1 of the second gate cut GC2 may isolate the third bottom gate electrode BG3 from the fourth bottom gate electrode BG4 in the second horizontal direction DR2.

The second portion GC2_2 of the second gate cut GC2 may be disposed inside the second gate cut trench GCT2 formed between the third upper gate electrode UG3 and the fourth upper gate electrode UG4. The second portion GC2_2 of the second gate cut GC2 may isolate the third upper gate electrode UG3 from the fourth upper gate electrode UG4 in the second horizontal direction DR2. The second gate cut GC2 may have the same structure as that of the first gate cut GC1. Therefore, a description of a detailed structure of the second gate cut GC2 is omitted. Each of the first gate cut GC1 and the second gate cut GC2 may include, but not be limited to, at least one of silicon nitride (SiN), silicon oxynitride (SiON), silicon oxide (SiO₂), silicon oxycarbonitride (SiOCN), and a combination thereof.

The first bottom source/drain contact BCA1 may be disposed inside the first interlayer insulating layer 140. The first bottom source/drain contact BCA1 may be connected to the first bottom source/drain region BSD1. The first bottom source/drain contact BCA1 may be extended in the second horizontal direction DR2 toward the second active pattern F2. That is, at least a portion of the first bottom source/drain contact BCA1 may be disposed on the field insulating layer 105 disposed between the first active pattern F1 and the second active pattern F2.

The second bottom source/drain contact BCA2 may be disposed inside the first interlayer insulating layer 140. The second bottom source/drain contact BCA2 may be connected to the second bottom source/drain region BSD2. The second bottom source/drain contact BCA2 may be extended in a direction opposite to the second horizontal direction DR2 toward the first active pattern F1. That is, at least a portion of the second bottom source/drain contact BCA2 may be disposed on the field insulating layer 105 disposed between the first active pattern F1 and the second active pattern F2. The second bottom source/drain contact BCA2 may be spaced apart from the first bottom source/drain contact BCA1 in the second horizontal direction DR2.

The first upper source/drain contact UCA1 may be disposed inside the first interlayer insulating layer 140. The first upper source/drain contact UCA1 may be connected to the first upper source/drain region USD1. The first upper source/drain contact UCA1 may be extended in a direction opposite to the second horizontal direction DR2. The first upper source/drain contact UCA1 does not overlap the first bottom source/drain contact BCA1 on the field insulating layer 105, which is disposed between the first active pattern F1 and the second active pattern F2, in the vertical direction DR3.

The second upper source/drain contact UCA2 may be disposed inside the first interlayer insulating layer 140. The second upper source/drain contact UCA2 may be connected to the second upper source/drain region USD2. The second upper source/drain contact UCA2 may be extended in the second horizontal direction DR2. The second upper source/drain contact UCA2 may not overlap the second bottom source/drain contact BCA2 on the field insulating layer 105, which is disposed between the first active pattern F1 and the second active pattern F2, in the vertical direction DR3.

For example, the upper surface of each of the first upper source/drain contact UCA1 and the second upper source/drain contact UCA2 may be formed on the same plane as that of the first interlayer insulating layer 140. However, the present disclosure is not limited in this regard. Each of the first bottom source/drain contact BCA1, the second bottom source/drain contact BCA2, the first upper source/drain contact UCA1 and the second upper source/drain contact UCA2 may include a conductive material.

Although FIG. 5 shows that each of the first bottom source/drain contact BCA1, the second bottom source/drain contact BCA2, the first upper source/drain contact UCA1 and the second upper source/drain contact UCA2 is formed of a single layer, this is for convenience of description. However, the present disclosure is not limited in this regard. That is, each of the first bottom source/drain contact BCA1, the second bottom source/drain contact BCA2, the first upper source/drain contact UCA1 and the second upper source/drain contact UCA2 may be formed of a multi-layer.

A first through via TV1 may be connected to the first bottom source/drain contact BCA1 by passing through the first interlayer insulating layer 140 in the vertical direction DR3. The first through via TV1 may be disposed on the field insulating layer 105 disposed between the first active pattern F1 and the second active pattern F2. The first through via TV1 may overlap each of the second portion GC1_2 of the first gate cut GC1 and the second portion GC2_2 of the second gate cut GC2 in the first horizontal direction DR1.

However, the first through via TV1 does not overlap each of the first portion GC1_1 of the first gate cut GC1_1 and the first portion GC2_1 of the second gate cut GC2 in the first horizontal direction DR1. Alternatively or additionally, the first through via TV1 does not overlap each of the first upper gate electrode UG1 and the third upper gate electrode UG3 in the first horizontal direction DR1.

A second through via TV2 may be connected to the second bottom source/drain contact BCA2 by passing through the first interlayer insulating layer 140 in the vertical direction DR3. The second through via TV2 may be disposed on the field insulating layer 105 disposed between the first active pattern F1 and the second active pattern F2. The second though via TV2 may be spaced apart from the first through via TV1 in the second horizontal direction DR2. The second through via TV2 may overlap each of the second portion GC1_2 of the first gate cut GC1 and the second portion GC2_2 of the second gate cut GC2 in the first horizontal direction DR1.

However, the second through via TV2 does not overlap each of the first portion GC1_1 of the first gate cut GC1_1 and the second portion GC2_1 of the second gate cut GC2 in the first horizontal direction DR1. Alternatively or additionally, the second through via TV2 does not overlap each of the second upper gate electrode UG2 and the fourth upper gate electrode UG4 in the first horizontal direction DR1.

For example, an upper surface of each of the first through via TV1 and the second through via TV2 may be formed on the same plane as the upper surface of the first interlayer insulating layer 140. However, the present disclosure is not limited in this regard. Each of the first through via TV1 and the second through via TV2 may include a conductive material. Although FIG. 5 shows that each of the first through via TV1 and the second through via TV2 is formed of a single layer, this is for convenience of description. However, the present disclosure is not limited in this regard. That is, each of the first through via TV1 and the second through via TV2 may be formed of a multi-layer.

The first gate contact CB1 may be connected to the first upper gate electrode UG1 by passing through the capping pattern 123 in the vertical direction DR3. The second gate contact CB2 may be connected to the second upper gate electrode UG2 by passing through the capping pattern 123 in the vertical direction DR3. The third gate contact CB3 may be connected to the third upper gate electrode UG3 by passing through the capping pattern 123 in the vertical direction DR3. In some embodiments, the fourth gate contact may be connected to the fourth upper gate electrode UG4 by passing through the capping pattern 123 in the vertical direction DR3 (not shown).

For example, an upper surface of each of the first to fourth gate contacts CB1 to CB4 may be formed on the same plane as the upper surface of the first interlayer insulating layer 140. However, the present disclosure is not limited in this regard. Each of the first to fourth gate contacts CB1 to CB4 may include a conductive material. Although FIGS. 4 and 6 show that each of the first to fourth gate contacts CB1 to CB4 is formed of a single layer, this is for convenience of description. However, the present disclosure is not limited in this regard. That is, each of the first to fourth gate contacts CB1 to CB4 may be formed of a multi-layer.

The etch stop layer 150 may be disposed on the first interlayer insulating layer 140. The etch stop layer 150 may be formed to be conformal, for example. FIGS. 4 to 8 show that the etch stop layer 150 is formed of a single layer. However, the present disclosure is not limited in this regard. For example, in some embodiments, the etch stop layer 150 may be formed of a multi-layer. The etch stop layer 150 may include, but not be limited to, at least one of aluminum oxide (Al₂O₃), aluminum nitride (AlN), hafnium oxide (HfO₂), zirconium oxide (ZrO₂), silicon oxide (SiO₂), silicon nitride (SiN), silicon oxynitride (SiON), or a low dielectric constant material.

The second interlayer insulating layer 160 may be disposed on the etch stop layer 150. For example, the second interlayer insulating layer 160 may include, but not be limited to, at least one of silicon oxide (SiO₂), silicon nitride (SiN), silicon oxynitride (SiON), or a low dielectric constant material. The first via V1 may be connected to each of the first to third gate contacts CB1, CB2 and CB3 by passing through the second interlayer insulating layer 160 and the etch stop layer 150 in the vertical direction DR3. The second via V2 may be connected to each of the first and second through vias TV1 and TV2 by passing through the second interlayer insulating layer 160 and the etch stop layer 150 in the vertical direction DR3. The third via V3 may be connected to each of the first and second upper source/drain contacts UCA1 and UCA2 by passing through the second interlayer insulating layer 160 and the etch stop layer 150 in the vertical direction DR3.

Each of the first to third vias V1, V2 and V3 may include a conductive material. Although FIGS. 4 to 7 show that each of the first to third vias V1, V2 and V3 is formed of a single layer, this is for convenience of description. However, the present disclosure is not limited in this regard. That is, each of the first to third vias V1, V2 and V3 may be formed of a multi-layer.

In the semiconductor device, according to some embodiments of the present disclosure, in the structure in which the upper gate electrodes UG1 and UG2 are stacked on the bottom gate electrodes BG1 and BG2, the width W2 of the portion GC1_2 of the gate cut GC1, which isolates the upper gate electrodes UG1 and UG2, may be greater than the width W1 of another portion GC1_1 of the gate cut GC1, which isolates the bottom gate electrodes BG1 and BG2. Therefore, in the semiconductor device, according to some embodiments of the present disclosure, the through vias TV1 and TV2 connected to the bottom source/drain contacts BCA1 and BCA2 may be formed so as not to overlap the upper gate electrodes UG1 and UG2 in the horizontal direction, and, as a result, a short may be prevented from occurring between the upper gate electrodes UG1 and UG2 and the through vias TV1 and TV2.

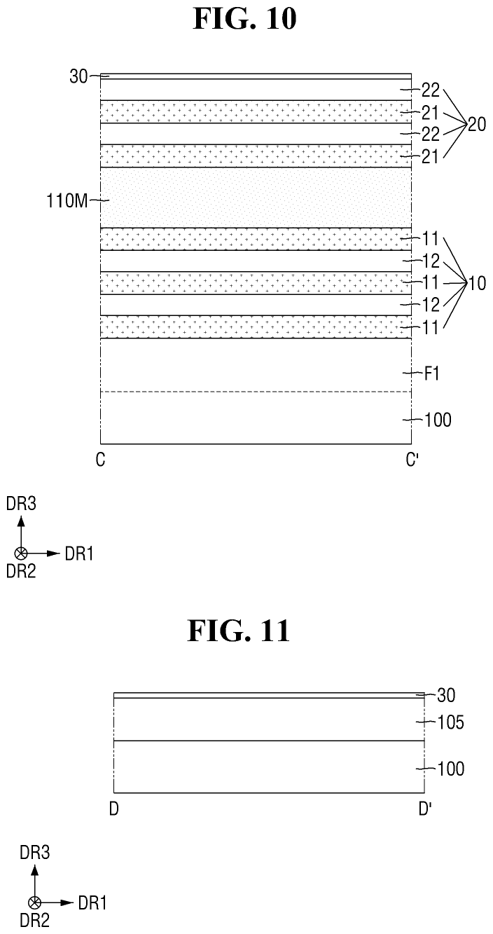

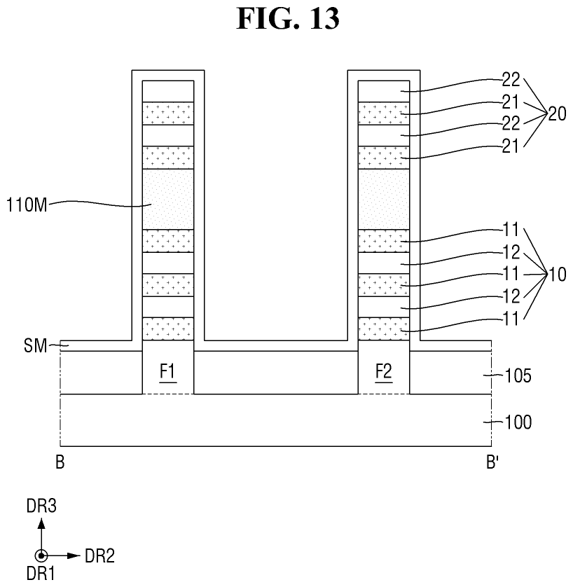

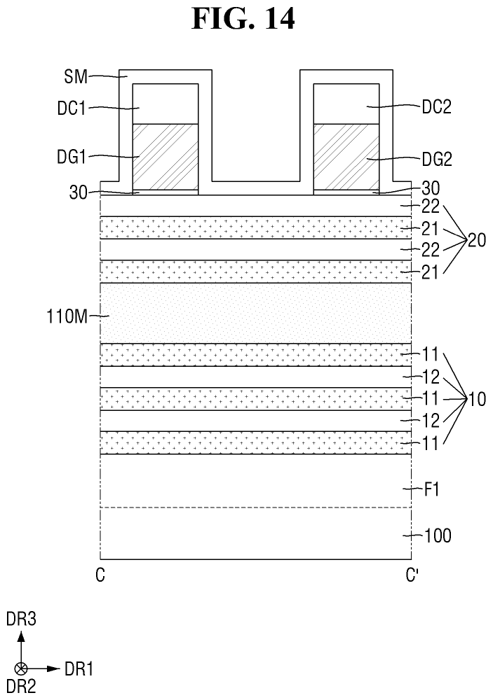

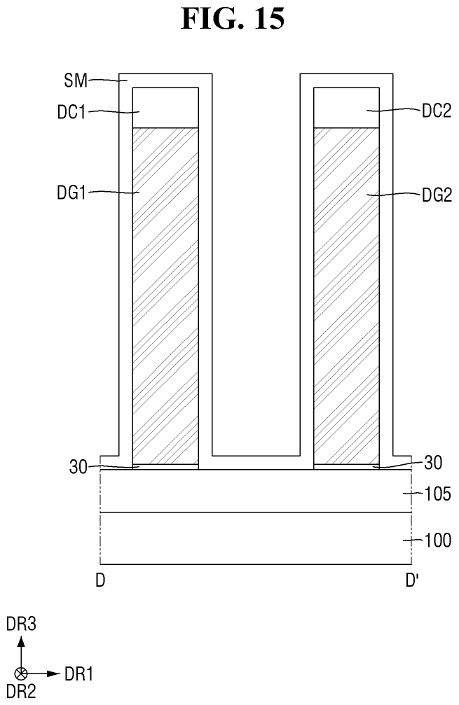

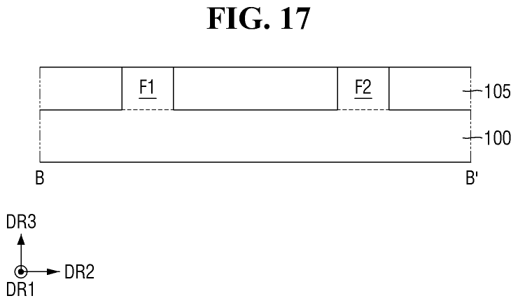

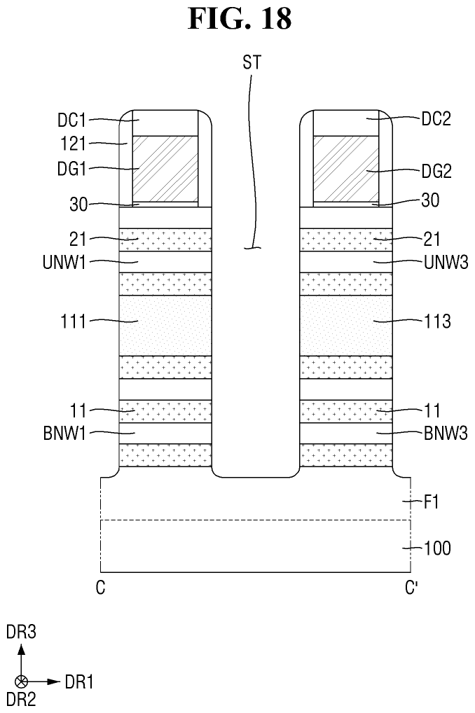

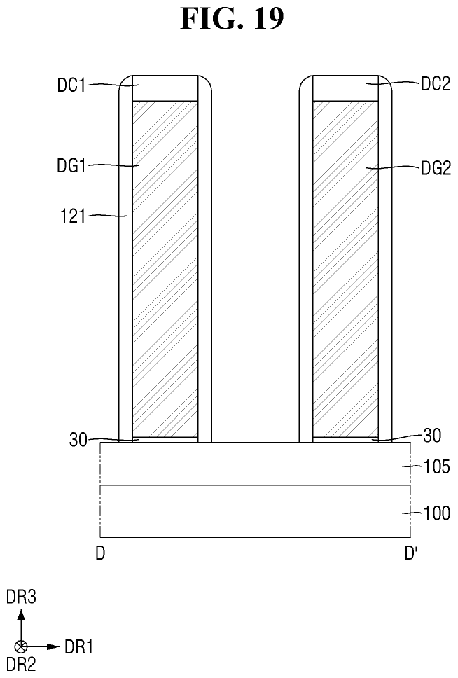

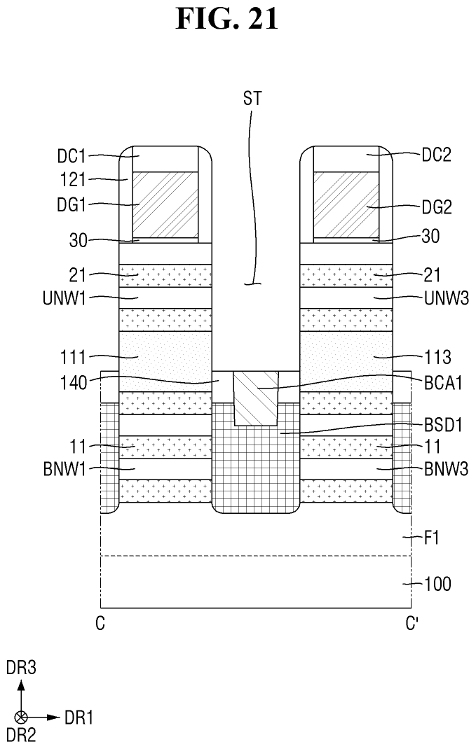

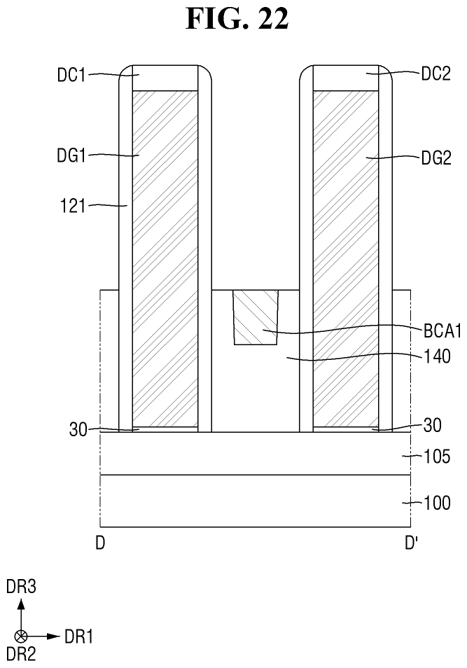

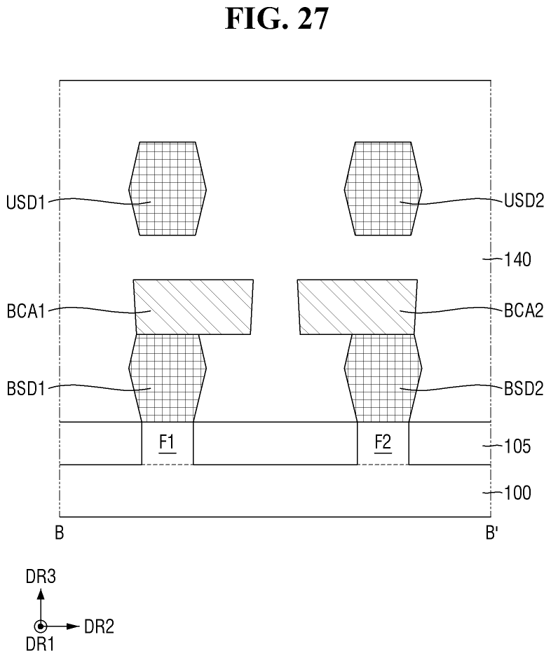

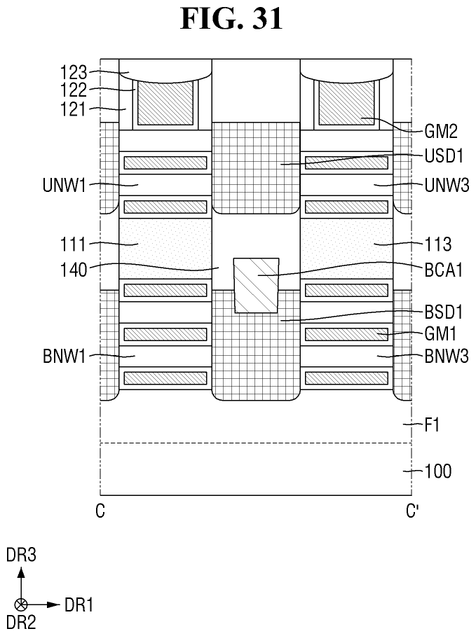

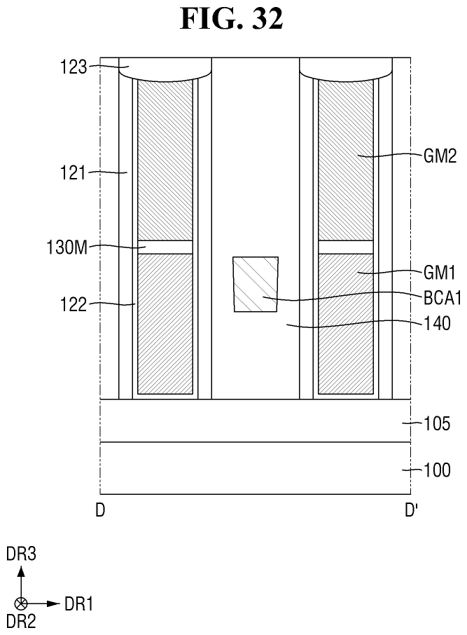

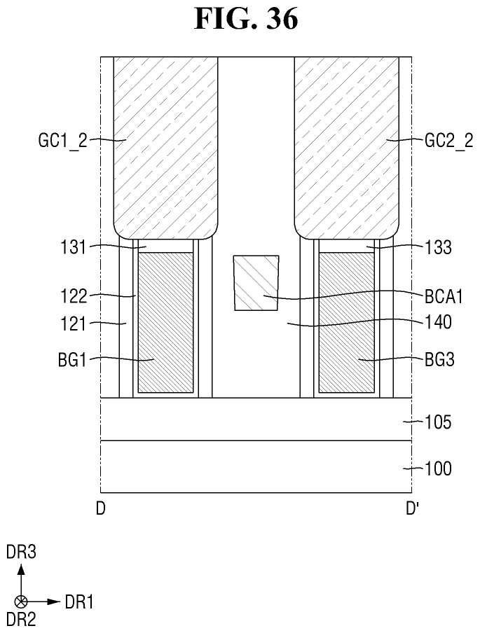

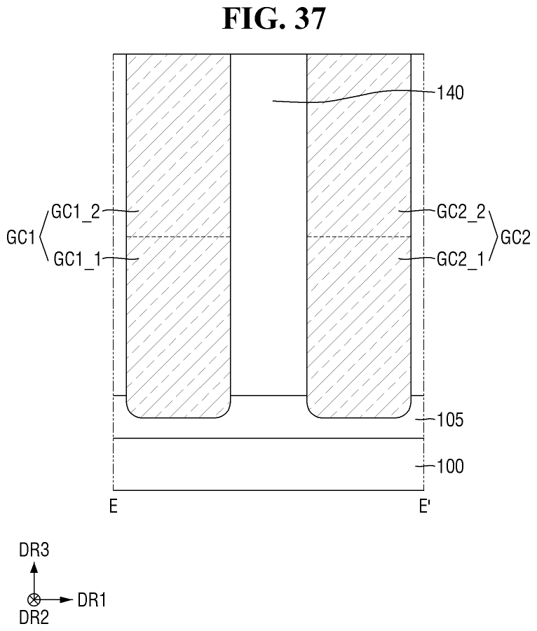

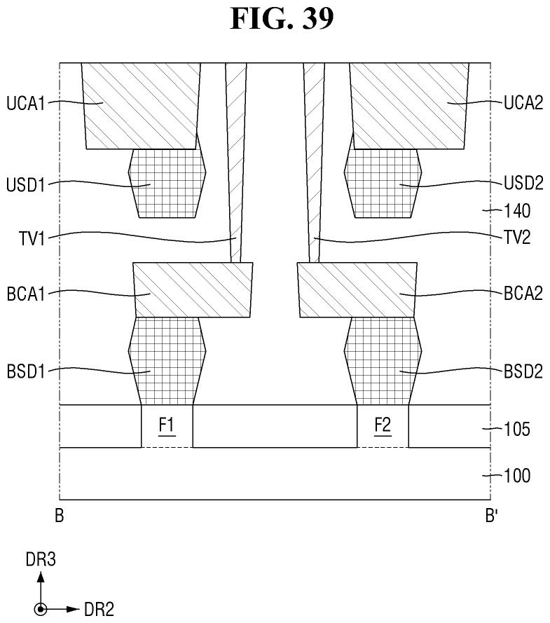

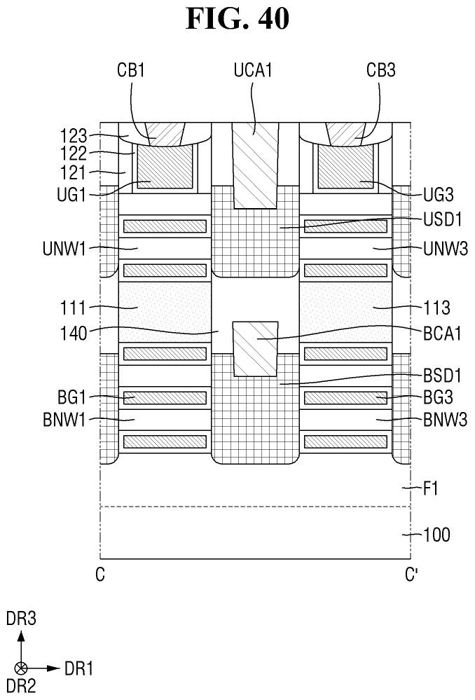

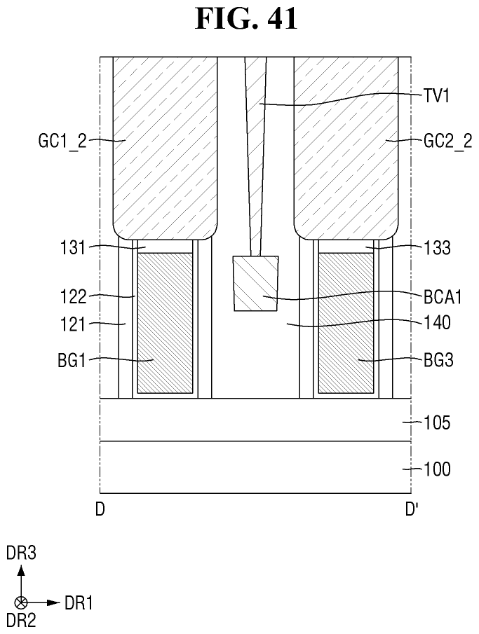

Hereinafter, a method of manufacturing a semiconductor device, according to some embodiments of the present disclosure, is described with reference to FIGS. 4 to 41.

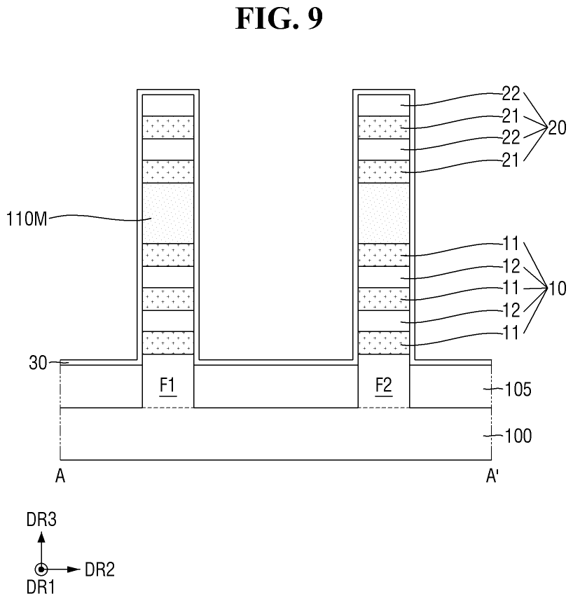

FIGS. 9 to 41 are views illustrating intermediate steps to describe a method of manufacturing a semiconductor device, according to some embodiments of the present disclosure.

Referring to FIGS. 9 to 11, a first stacked structure 10, an isolation material layer 110M and a second stacked structure 20 may be sequentially stacked on a substrate 100. The first stacked structure 10 may include a first sacrificial layer 11 and a first semiconductor layer 12, which are alternately stacked on the substrate 100. For example, the first sacrificial layer 11 may be formed at each of bottommost and uppermost portions of the first stacked structure 10. However, the present disclosure is not limited in this regard. For example, in some embodiments, a first semiconductor layer 12 may be formed on the uppermost portion of the first stacked structure 10.

For example, a thickness of the isolation material layer 110M in the vertical direction DR3 may be greater than that of the first sacrificial layer 11 in the vertical direction DR3. The isolation material layer 110M may include, but not be limited to, at least one of silicon nitride (SiN), silicon oxycarbonitride (SiOCN), silicon boron carbonitride (SiBCN), silicon carbonitride (SiCN), silicon oxynitride (SiON), and a combination thereof.

The second stacked structure 20 may include a second sacrificial layer 21 and a second semiconductor layer 22, which are alternately stacked on the isolation material layer 110M. For example, the second sacrificial layer 21 may be formed at a bottommost portion of the second stacked structure 20, and the second semiconductor layer 22 may be formed at an uppermost portion of the second stacked structure 20. However, the present disclosure is not limited in this regard. For example, in some embodiments, the second sacrificial layer 21 may be also formed on the uppermost portion of the second stacked structure 20. Each of the first sacrificial layer 11 and the second sacrificial layer 21 may include, for example, silicon germanium (SiGe). Each of the first semiconductor layer 12 and the second semiconductor layer 22 may include, for example, silicon (Si).

Subsequently, the first stacked structure 10, the isolation material layer 110M, the second stacked structure 20 and the substrate 100 may be partially etched to form the first active pattern F1 and the second active pattern F2 on the substrate 100. Each of the first active pattern F1 and the second active pattern F2 may be extended in the first horizontal direction DR1. The second active pattern F2 may be spaced apart from the first active pattern F1 in the second horizontal direction DR2.

Subsequently, a field insulating layer 105 surrounding sidewalls of the active pattern 101 may be formed on the substrate 100. For example, the active pattern 101 may be more protruded in the vertical direction DR3 than an upper surface of the field insulating layer 105. Subsequently, a pad oxide layer 30 may be formed to cover each of the field insulating layer 105, the first stacked structure 10, the isolation material layer 110M and the second stacked structure 20. For example, the pad oxide layer 30 may be formed to be conformal. The pad oxide layer 30 may include, for example, silicon oxide (SiO₂).

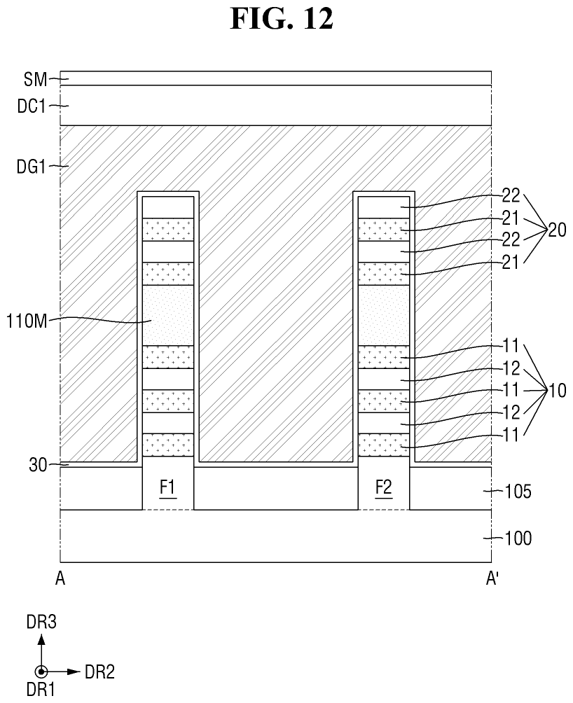

Referring to FIGS. 12 to 15, first and second dummy gates DG1 and DG2 may be formed on the pad oxide layer 30 on the field insulating layer 105, the first stacked structure 10, the isolation material layer 110M and the second stacked structure 20. Each of the first and second dummy gates DG1 and DG2 may be extended in the second horizontal direction DR2. The second dummy gate DG2 may be spaced apart from the first dummy gate DG1 in the first horizontal direction DR1. Alternatively or additionally, a first dummy capping pattern DC1 may be formed on the first dummy gate DG1, and a second dummy capping pattern DC2 may be formed on the second dummy gate DG2. For example, a portion of the pad oxide layer 30, except a portion overlapped with each of the first and second dummy gates DG1 and DG2 in the vertical direction DR3, may be removed.

Subsequently, a spacer material layer SM may be formed to cover sidewalls of each of the first and second dummy gates DG1 and DG2, sidewalls and upper surfaces of the first and second dummy capping patterns DC1 and DC2, sidewalls of the first stacked structure 10, sidewalls of the isolation material layer 110M, sidewalls and the upper surface of the second stacked structure 20, and the upper surface of the field insulating layer 105. For example, the spacer material layer SM may be formed to be conformal. The spacer material layer SM may include, but not be limited to, at least one of silicon nitride (SiN), silicon oxycarbonitride (SiOCN), silicon boron carbonitride (SiBCN), silicon carbonitride (SiCN), silicon oxynitride (SiON), and a combination thereof.

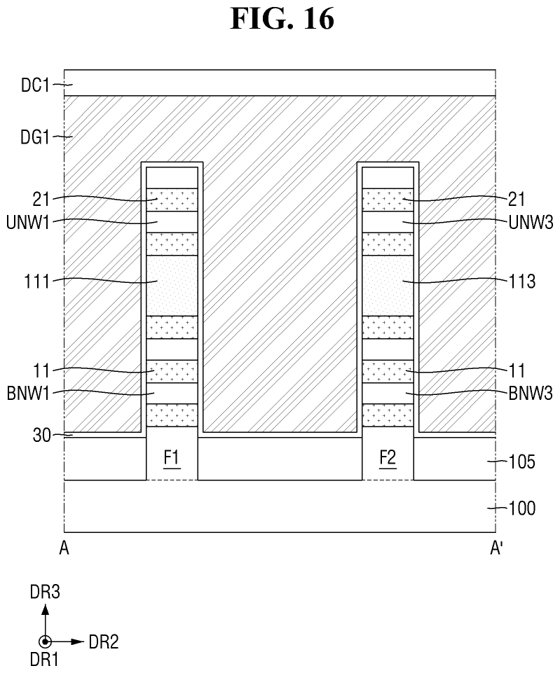

Referring to FIGS. 16 to 19, the first stacked structure 10, the isolation material layer 110M and the second stacked structure 20 may be etched using the first and second dummy capping patterns DC1 and DC2 and the first and second dummy gates DG1 and DG2 as masks to form a source/drain trench ST. That is, the source/drain trench ST may be formed between the first dummy gate DG1 and the second dummy gate DG2 on each of the first and second active patterns F1 and F2. For example, the source/drain trench ST may be extended into each of the first and second active patterns F1 and F2.

While the source/drain trench ST is being formed, a portion of the spacer material layer (SM of FIGS. 12 to 15) and the first and second dummy capping patterns DC1 and DC2, which are formed on the upper surfaces of the first and second dummy capping patterns DC1 and DC2, may be removed. The spacer material layer (e.g., SM of FIGS. 12 to 15) remaining on the sidewalls of the first and second dummy capping patterns DC1 and DC2 and the first and second dummy gates DG1 and DG2 may be referred to as a gate spacer 121.

For example, after the source/drain trench ST is formed, the first semiconductor layer (e.g., first semiconductor layer 12 of FIGS. 12 to 15) and the second semiconductor layer (e.g., second semiconductor layer 22 of FIGS. 12 to 15) remaining below the first dummy gate DG1 on the first active pattern F1 may be referred to as a plurality of first bottom nanosheets BNW1 and a plurality of first upper nanosheets UNW1, respectively. Alternatively or additionally, the first semiconductor layer (e.g., first semiconductor layer 12 of FIGS. 12 to 15) and the second semiconductor layer (e.g., second semiconductor layer 22 of FIGS. 12 to 15), which remain below the second dummy gate DG2 on the first active pattern F1, may be referred to as a plurality of third bottom nanosheets BNW3 and a plurality of third upper nanosheets UNW3, respectively. Alternatively or additionally, the isolation material layer (e.g., isolation material layer 110M of FIGS. 12 to 15) remaining below the first dummy gate DG21 on the first active pattern F1 may be referred to as a first isolation layer 111. The isolation material layer (e.g., isolation material layer 110M of FIGS. 12 to 15) remaining below the second dummy gate DG2 on the first active pattern F1 may be referred to as a third isolation layer 113.

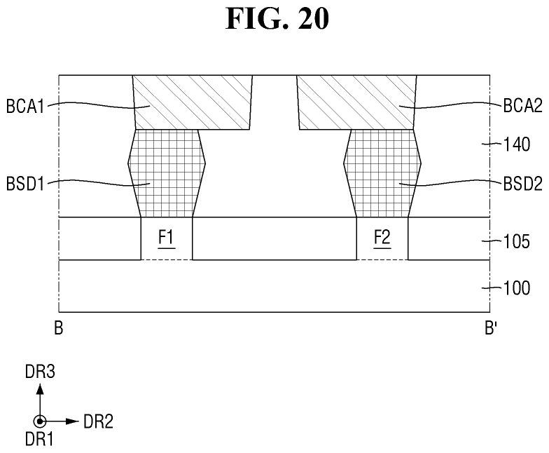

Referring to FIGS. 20 to 22, each of a first bottom source/drain region BSD1 and a second bottom source/drain region BSD2 may be formed below the source/drain trench ST. For example, the first bottom source/drain region BSD1 may be formed on the first active pattern F1, and the second bottom source/drain region BSD2 may be formed on the second active pattern F2. For another example, upper surfaces of the first and second bottom source/drain regions BSD1 and BSD2 may be formed to be lower than a lower surface of the first isolation layer 111. However, the present disclosure is not limited in this regard.

Subsequently, a first interlayer insulating layer 140 may be formed on the field insulating layer 105 to cover each of the first and second bottom source/drain regions BSD1 and BSD2. For example, an upper surface of the first interlayer insulating layer 140 may be formed between the lower surface and an upper surface of the first isolation layer 111.

Alternatively or additionally, inside the first interlayer insulating layer 140, a first bottom source/drain contact BCA1 may be formed on the first bottom source/drain region BSD1, and a second bottom source/drain contact BCA2 may be formed on the second bottom source/drain region BSD2. The first bottom source/drain contact BCA1 may be connected to the first bottom source/drain region BSD1, and the second bottom source/drain contact BCA2 may be connected to the second bottom source/drain region BSD2. For example, upper surfaces of each of the first and second bottom source/drain contacts BCA1 and BCA2 may be formed on the same plane as the upper surface of the first interlayer insulating layer 140.

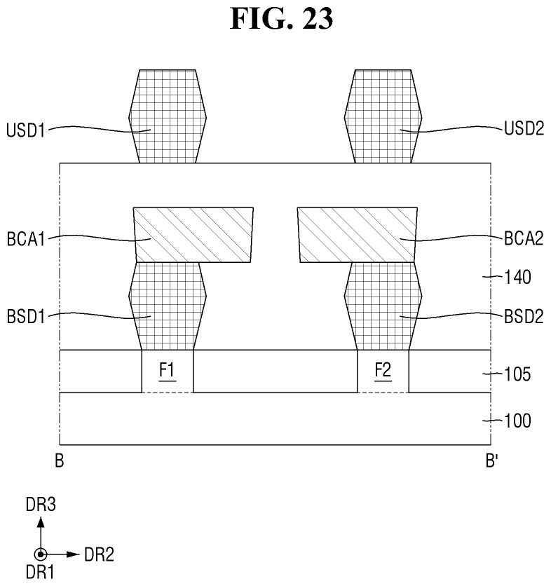

Referring to FIGS. 23 to 25, the first interlayer insulating layer 140 may be additionally formed to cover the upper surfaces of the first and second bottom source/drain contacts BCA1 and BCA2. For example, the upper surface of the first interlayer insulating layer 140, which may be additionally formed, may be higher than that of the first isolation layer 111. However, the present disclosure is not limited in this regard.

Subsequently, each of first and second upper source/drain regions USD1 and USD2 may be formed on the upper surface of the first interlayer insulating layer 140 that is additionally formed. The first upper source/drain region USD1 may be formed on the first bottom source/drain region BSD1, and the second upper source/drain region USD2 may be formed on the second bottom source/drain region BSD2.

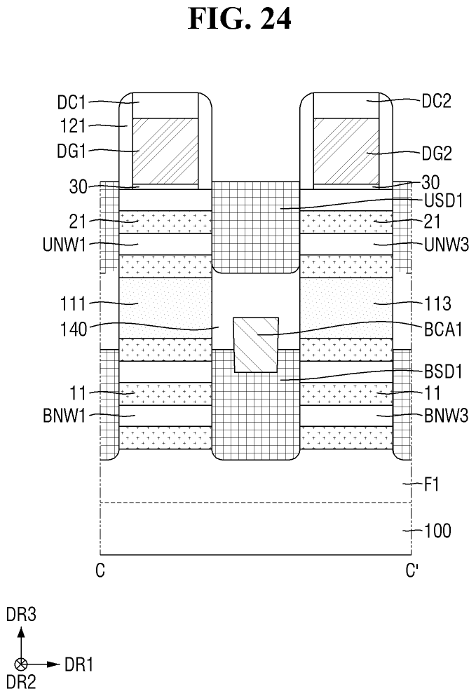

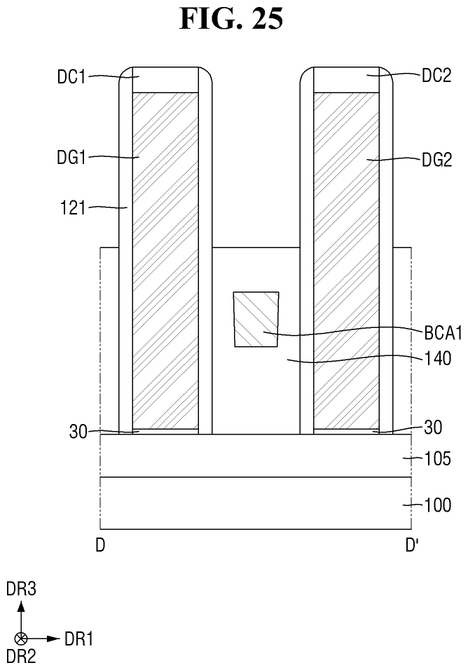

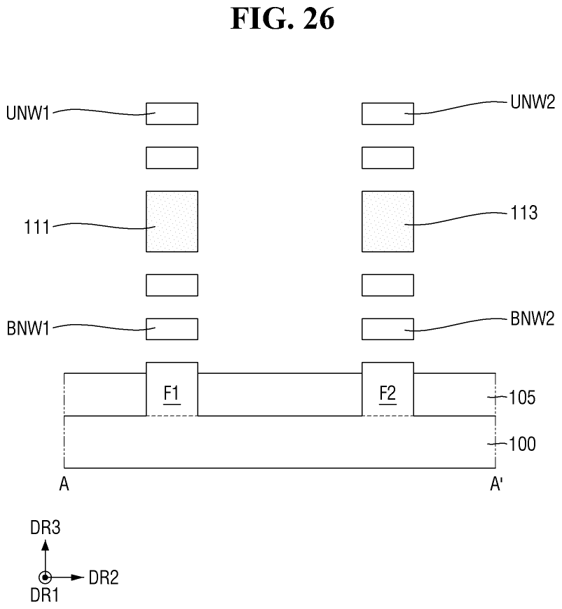

Referring to FIGS. 26 to 29, the first interlayer insulating layer 140 may be additionally formed to cover each of the first and second upper source/drain regions USD1 and USD2. The first interlayer insulating layer 140 may cover the first and second dummy capping patterns (DC1 and DC2 of FIGS. 24 and 25).

Subsequently, upper surfaces of the first and second dummy gates (DG1 and DG2 of FIGS. 24 and 25) may be exposed through a planarization process. Subsequently, each of the first and second dummy gates (e.g., DG1 and DG2 of FIG. 24), the first sacrificial layer (e.g., first sacrificial layer 11 of FIG. 24), the second sacrificial layer (e.g., second sacrificial layer 21 in FIG. 24) and the pad oxide layer (e.g., pad oxide layer 30 of FIG. 24 and FIG. 25) may be removed. The portion from which the first dummy gate (e.g., first dummy gate DG1 of FIG. 24) is removed may be referred to as a first gate trench GT1, and the portion from which the second dummy gate (e.g., second dummy gate DG2 of FIG. 24) is removed may be referred to as a second gate trench GT2.

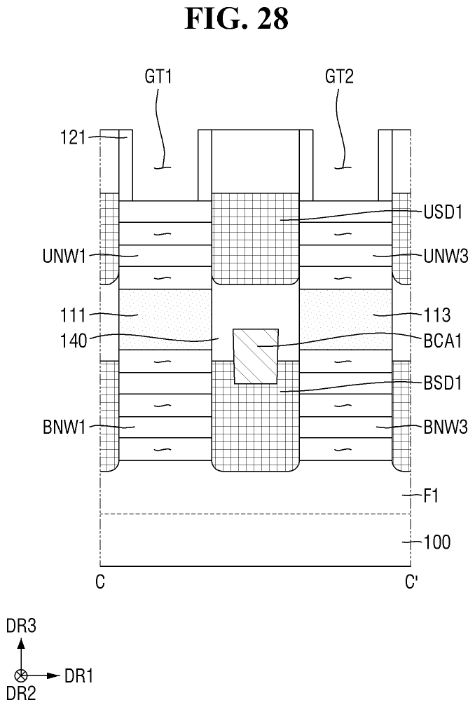

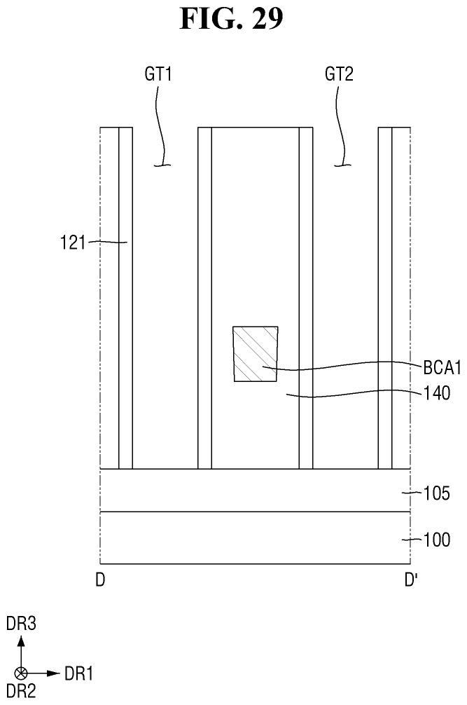

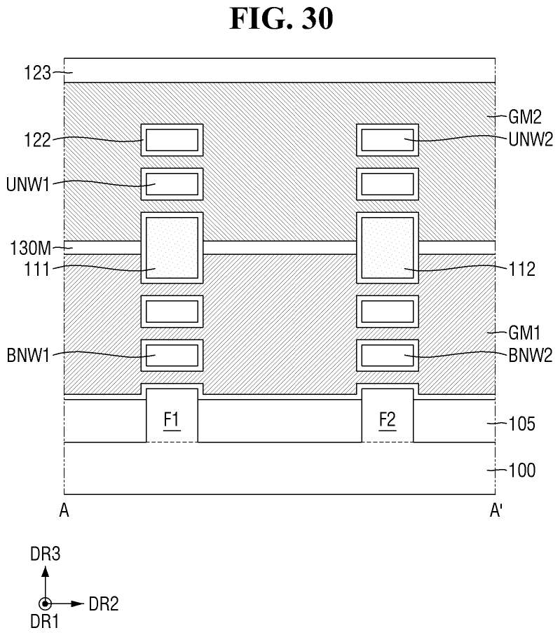

Referring to FIGS. 30 to 32, a gate insulating layer 122 may be formed inside each of the first and second gate trenches (e.g., first and second gate trenches GT1 and GT2 of FIGS. 28 and 29). Subsequently, a first gate material layer GM1 surrounding each of first to third bottom nanosheets BNW1, BNW2 and BNW3 may be formed inside each of the first and second gate trenches (e.g., first and second gate trenches GT1 and GT2 of FIGS. 28 and 29). For example, an upper surface of the first gate material layer GM1 may be formed between the lower surface and the upper surface of the first isolation layer 111.

Subsequently, a gate isolation material layer 130M may be formed on the first gate material layer GM1 inside each of the first and second gate trenches (e.g., first and second gate trenches GT1 and GT2 of FIGS. 28 and 29). For example, the gate isolation material layer 130M may be formed between the lower surface and the upper surface of the first isolation layer 111. Then, a second gate material layer GM2 may be formed on the gate isolation material layer 130M inside each of the first and second gate trenches (e.g., first and second gate trenches GT1 and GT2 of FIGS. 28 and 29). Subsequently, a capping pattern 123 may be formed on the second gate material layer GM2.

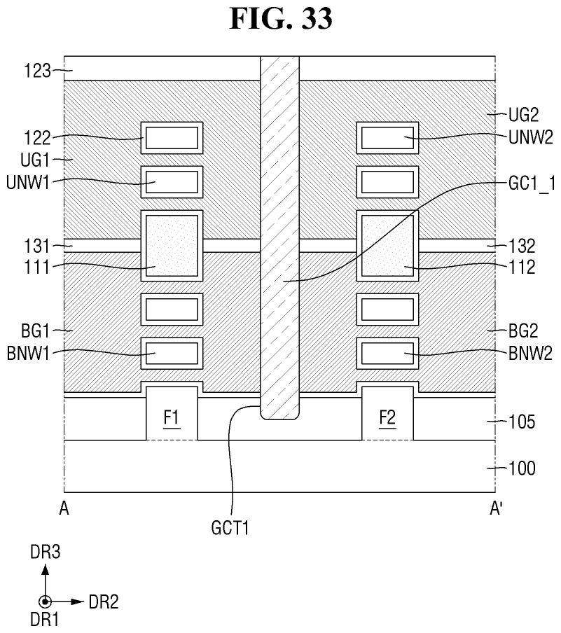

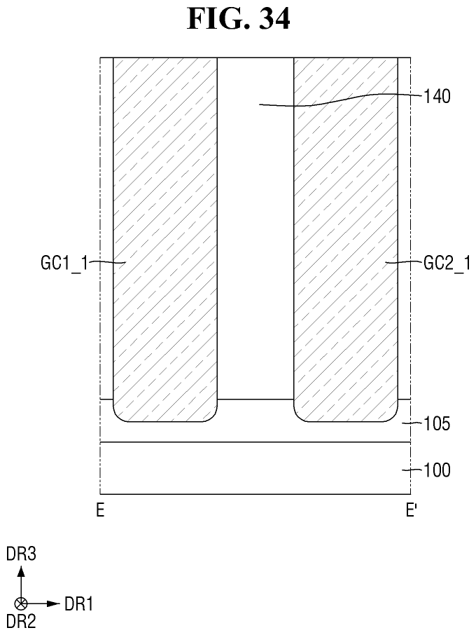

Referring to FIGS. 33 and 34, for example, a first gate cut GCT1 extended into the field insulating layer 105 may be formed by passing through the capping pattern 123, the second gate material layer (e.g., second gate material layer GM2 of FIGS. 30 to 32), the gate isolation material layer (e.g., gate isolation material layer 130M of FIGS. 30 to 32) and the first gate material layer (e.g., first gate material layer GM1 of FIGS. 30 to 32) in the vertical direction DR3.

Subsequently, a first portion GC1_1 of the first gate cut GC1 may be formed inside the first gate cut trench GCT1. The first portion GC1_1 of the first gate cut GC1 may isolate the capping pattern 123, the second gate material layer (e.g., second gate material layer GM2 of FIGS. 30 to 32), the gate isolation material layer (e.g., gate isolation material layer 130M of FIGS. 30 to 32) and the first gate material layer (e.g., first gate material layer GM1 of FIGS. 30 to 32) from one another in the second horizontal direction DR2.

After the first portion GC1_1 of the first gate cut GC1 is formed, the first gate material layer (e.g., first gate material layer GM1 of FIGS. 30 to 32), the gate isolation material layer (e.g., gate isolation material layer 130M of FIGS. 30 to 32) and the second gate material layer (e.g., second gate material layer GM2 of FIGS. 30 to 32), which are disposed on the first active pattern F1, may be referred to as a first bottom gate electrode BG1, a first gate isolation layer 131 and a first upper gate electrode UG1, respectively. Alternatively or additionally, after the first portion GC1_1 of the first gate cut GC1_1 is formed, the first gate material layer (e.g., first gate material layer GM1 of FIGS. 30 to 32), the gate isolation material layer (e.g., gate isolation material layer 130M of FIGS. 30 to 32) and the second gate material layer (e.g., second gate material layer GM2 of FIGS. 30 to 32), which are disposed on the second active pattern F2, may be referred to as a second bottom gate electrode BG2, a second gate isolation layer 132 and a second upper gate electrode UG2, respectively.

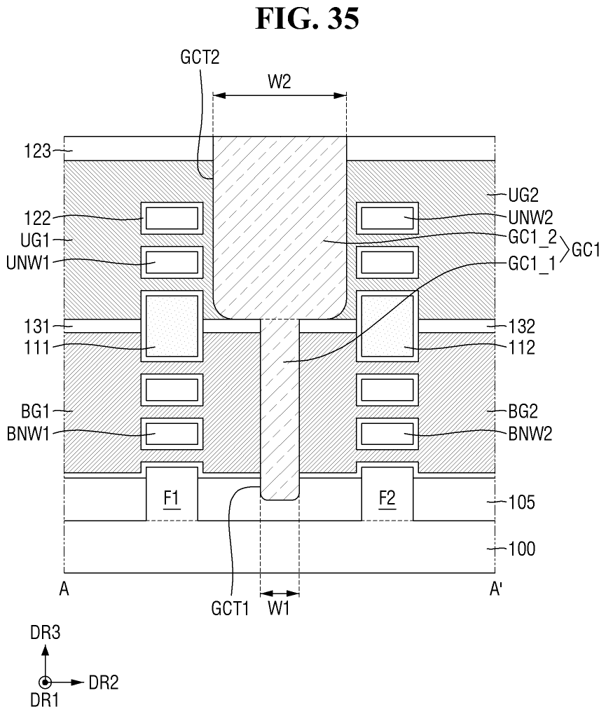

Referring to FIGS. 35 to 37, the first portion GC1_1 of the first gate cut GC1, a portion of the first upper gate electrode UG1, a portion of the second upper gate electrode UG2 and a portion of the capping pattern 123, which are formed on the upper surface of each of the first and second gate isolation layers 131 and 132, may be etched to form a second gate cut trench GTC2. The second gate cut trench GTC2 may expose an upper surface of each of the first and second gate isolation layers 131 and 132. A width of the second gate cut trench GTC2 in the second horizontal direction DR2 may be greater than that of the first gate cut trench GTC1 in the second horizontal direction DR2.

Subsequently, a second portion GC1_2 of the first gate cut GC1 may be formed inside the second gate cut trench GTC2. For example, a width W2 of the second portion GC1_2 of the first gate cut GC1 in the second horizontal direction DR2 may be greater than a width W1 of the first portion GC1_1 of the first gate cut GC1 in the second horizontal direction DR2. For another example, an upper surface of the second portion GC1_2 of the first gate cut GC1 may be formed on the same plane as that of the capping pattern 123. For another example, the second portion GC1_2 of the first gate cut GC1 and the first portion GC1_1 of the first gate cut GC1 may include the same material. However, the present disclosure is not limited in this regard.

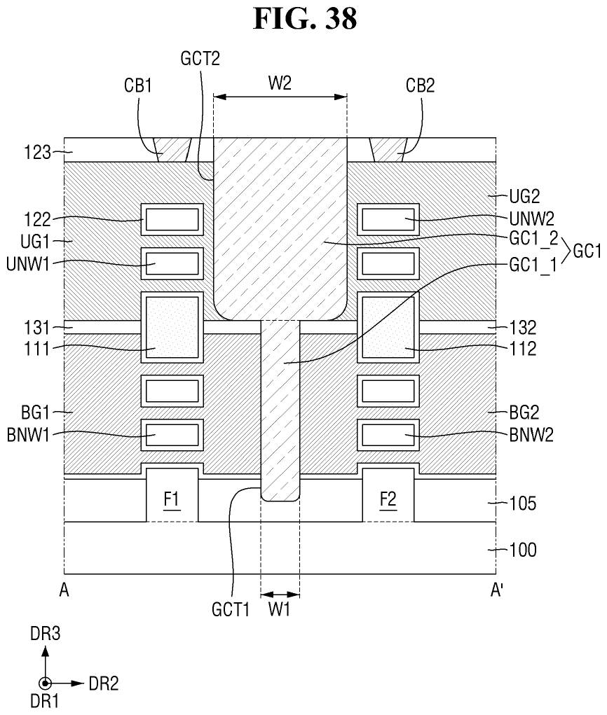

Referring to FIGS. 38 to 41, first to third gate contacts CB1, CB2 and CB3 respectively connected to the first to third upper gate electrodes UG1, UG2 and UG3 may be formed by passing through the capping pattern 123 in the vertical direction DR3.

Alternatively or additionally, first and second upper source/drain contacts UCA1 and UCA2 respectively connected to the first and second upper source/drain regions USD1 and USD2 may be formed by passing through the first interlayer insulating layer 140 in the vertical direction DR3.

In some embodiments, a first through via TV1 connected to the first bottom source/drain contact BCA1 by passing through the first interlayer insulating layer 140 in the vertical direction DR3 may be formed between the first upper source/drain region USD1 and the second upper source/drain region USD2. A second through via TV2 connected to the second bottom source/drain contact BCA2 by passing through the first interlayer insulating layer 140 in the vertical direction DR3 may be formed between the first upper source/drain region USD1 and the second upper source/drain region USD2.

Referring to FIGS. 4 to 8, an etch stop layer 150 and a second interlayer insulating layer 160 may be sequentially formed on the first interlayer insulating layer 140.

Subsequently, a first via V1 connected to each of the first to third gate contacts CB1, CB2 and CB3 by passing through the second interlayer insulating layer 160 and the etch stop layer 150 in the vertical direction DR3 may be formed. A second via V2 connected to each of the first and second through vias TV1 and TV2 by passing through the second interlayer insulating layer 160 and the etch stop layer 150 in the vertical direction DR3 may be formed. A third via V3 connected to each of the first and second upper source/drain contacts UCA1 and UCA2 by passing through the second interlayer insulating layer 160 and the etch stop layer 150 in the vertical direction DR3 may be formed. Through this manufacturing process, the semiconductor device shown in FIGS. 4 to 8 may be manufactured.

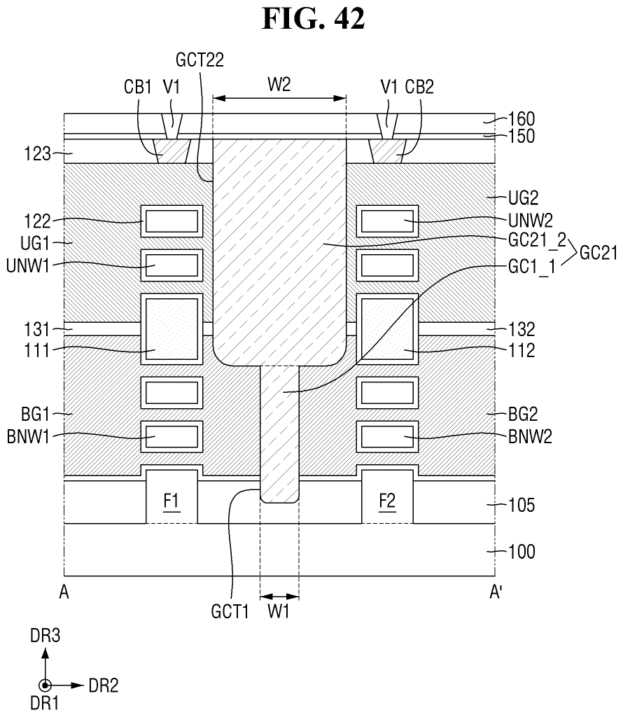

Hereinafter, a semiconductor device, according to some embodiments of the present disclosure, is described with reference to FIG. 42. The semiconductor depicted in FIG. 42 may include or may be similar in many respects to the semiconductor device described above with reference to FIGS. 4 to 8 and may include additional features not mentioned above. As such, the following description is based on differences from the semiconductor device shown in FIGS. 4 to 8.

FIG. 42 is a cross-sectional view illustrating a semiconductor device, according to some embodiments of the present disclosure.

Referring to FIG. 42, in the semiconductor device, according to some embodiments of the present disclosure, a second portion GC21_2 of a first gate cut GC21 may be in contact with each of the first bottom gate electrode BG1 and the second bottom gate electrode BG2.

For example, a second gate cut trench GTC22 may be extend into each of the first bottom gate electrode BG1 and the second bottom gate electrode BG2 by passing through the first gate isolation layer 131 and the second gate isolation layer 132 in the vertical direction DR3. The second portion GC21_2 of the first gate cut GC21 may be disposed inside the second gate cut trench GTC22. A portion of a lower surface and sidewalls of the second portion GC21_2 of the first gate cut GC21 may be in contact with each of the first bottom gate electrode BG1 and the second bottom gate electrode BG2.

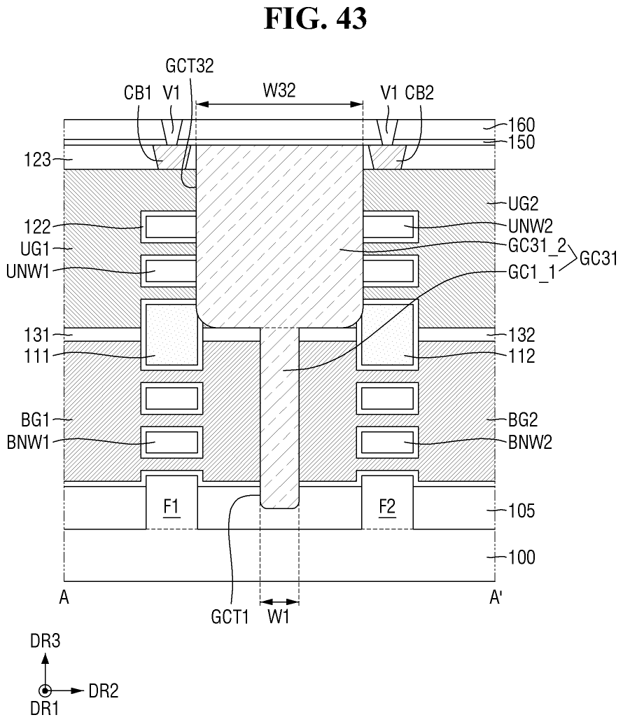

Hereinafter, a semiconductor device, according to some embodiments of the present disclosure, is described with reference to FIG. 43. The semiconductor depicted in FIG. 43 may include or may be similar in many respects to the semiconductor device described above with reference to FIGS. 4 to 8 and 42, and may include additional features not mentioned above. As such, the following description is based on differences from the semiconductor device shown in FIGS. 4 to 8.

FIG. 43 is a cross-sectional view illustrating a semiconductor device, according to some embodiments of the present disclosure.

Referring to FIG. 43, in the semiconductor device, according to some embodiments of the present disclosure, a second portion GC31_2 of a first gate cut GC31 may be in contact with each of the plurality of first upper nanosheets UNW1 and the plurality of second upper nanosheets UNW2.

For example, a second gate cut trench GTC32 may be formed by etching the gate insulating layer 122 formed on each of the plurality of first upper nanosheets UNW1 and the plurality of second upper nanosheets UNW2. The second gate cut trench GTC32 may expose each of the plurality of first upper nanosheets UNW1 and the plurality of second upper nanosheets UNW2. The second portion GC31_2 of the first gate cut GC31 may be disposed inside the second gate cut trench GTC32. Sidewalls of the second portion GC31_2 of the first gate cut GC31 may be in contact with each of the plurality of first upper nanosheets UNW1 and the plurality of second upper nanosheets UNW2. A width W32 of the second portion GC31_2 of the first gate cut GC31 in the second horizontal direction DR2 may be greater than a width W1 of the first portion GC1_1 of the first gate cut GC31 in the second horizontal direction DR2.

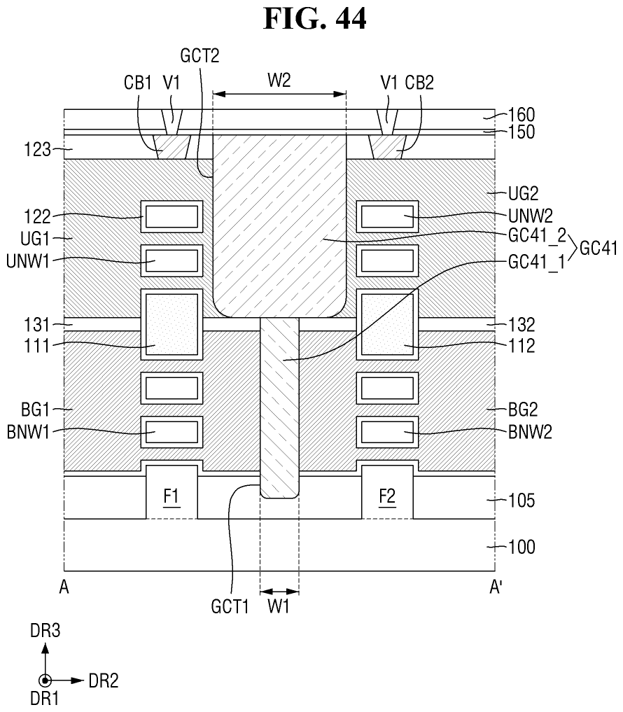

Hereinafter, a semiconductor device, according to some embodiments of the present disclosure, is described with reference to FIG. 44. The semiconductor depicted in FIG. 44 may include or may be similar in many respects to the semiconductor device described above with reference to FIGS. 4 to 8, 42, and 43, and may include additional features not mentioned above. As such, the following description is based on differences from the semiconductor device shown in FIGS. 4 to 8.

FIG. 44 is a cross-sectional view illustrating a semiconductor device, according to some embodiments of the present disclosure.

Referring to FIG. 44, in the semiconductor device, according to some embodiments of the present disclosure, a first portion GC41_1 of a first gate cut GC41 and a second portion GC41_2 of the first gate cut GC41 may include their respective materials different from each other.

For example, the first portion GC41_1 of the first gate cut GC41 may include, but not be limited to, any one of silicon nitride (SiN), silicon oxynitride (SiON), silicon oxide (SiO₂), silicon oxycarbonitride (SiOCN), and a combination thereof. Alternatively or additionally, the second portion GC41_2 of the first gate cut GC41 may include, but not be limited to, another one of silicon nitride (SiN), silicon oxynitride (SiON), silicon oxide (SiO₂), silicon oxycarbonitride (SiOCN), and a combination thereof.

For example, an upper surface of the first portion GC41_1 of the first gate cut GC41 may be in contact with a lower surface of the second portion GC41_2 of the first gate cut GC41. For example, the upper surface of the first portion GC41_1 of the first gate cut GC41 may be formed on the same plane as that of each of the first gate isolation layer 131 and the second gate isolation layer 132. However, the present disclosure is not limited in this regard.

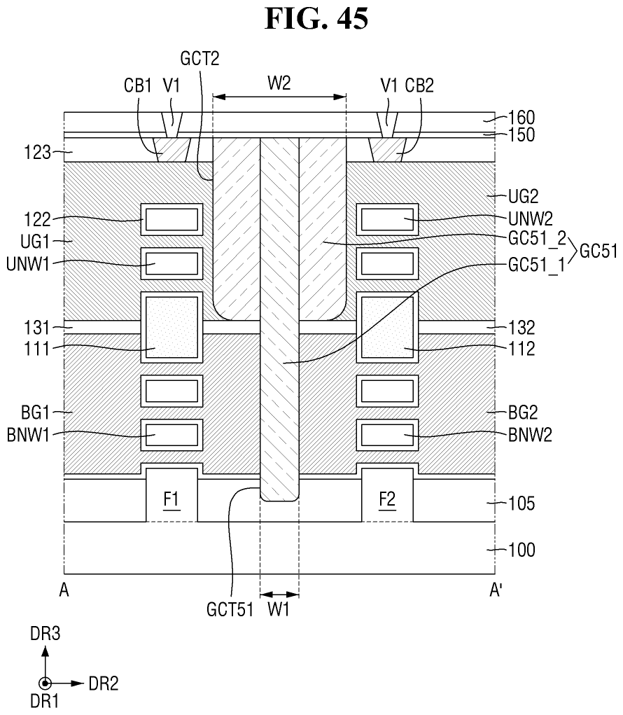

Hereinafter, a semiconductor device, according to some embodiments of the present disclosure, is described with reference to FIG. 45. The semiconductor depicted in FIG. 45 may include or may be similar in many respects to the semiconductor device described above with reference to FIGS. 4 to 8 and 42 to 44, and may include additional features not mentioned above. As such, the following description is based on differences from the semiconductor device shown in FIGS. 4 to 8.

FIG. 45 is a cross-sectional view illustrating a semiconductor device, according to some embodiments of the present disclosure.

Referring to FIG. 45, in the semiconductor device according to another embodiment of the present disclosure, a first portion GC51_1 of a first gate cut GC51 and a second portion GC51_2 of the first gate cut GC51 may include their respective materials different from each other.

For example, the first portion GC51_1 of the first gate cut GC51 may include, but not be limited to, any one of silicon nitride (SiN), silicon oxynitride (SiON), silicon oxide (SiO₂), silicon oxycarbonitride (SiOCN), and a combination thereof. Alternatively or additionally, the second portion GC51_2 of the first gate cut GC51 may include, but not be limited to, another one of silicon nitride (SiN), silicon oxynitride (SiON), silicon oxide (SiO₂), silicon oxycarbonitride (SiOCN), and a combination thereof.

For example, the first gate cut trench GTC51 may be extended in the vertical direction DR3 from the inside of the field insulating layer 105 to the upper surface of the capping pattern 123. The first portion GC51_1 of the first gate cut GC51 may be disposed inside the first gate cut trench GTC51. The second portion GC51_2 of the first gate cut GC51 may surround sidewalls of the first portion GC51_1 of the first gate cut GC51 in the second gate cut trench GTC2.

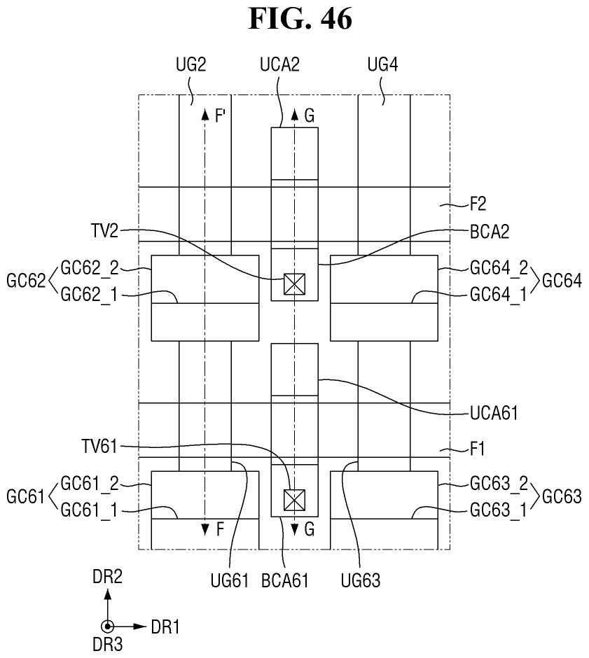

Hereinafter, a semiconductor device, according to some embodiments of the present disclosure, is described with reference to FIGS. 46 to 50. The semiconductor depicted in FIGS. 46 to 50 may include or may be similar in many respects to the semiconductor device described above with reference to FIGS. 4 to 8 and 42 to 45, and may include additional features not mentioned above. As such, the following description is based on differences from the semiconductor device shown in FIGS. 4 to 8.

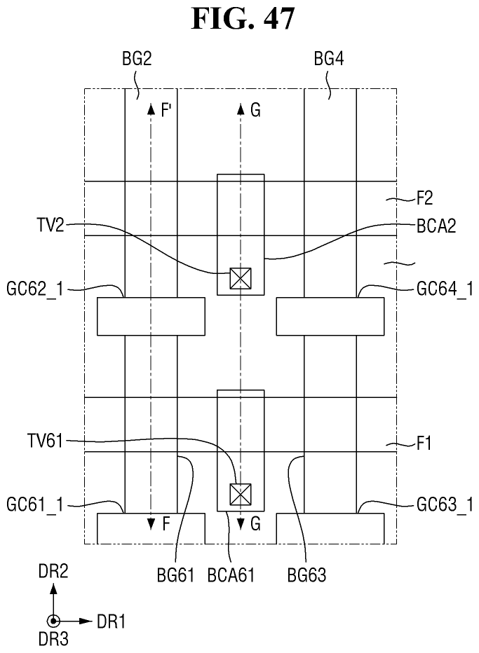

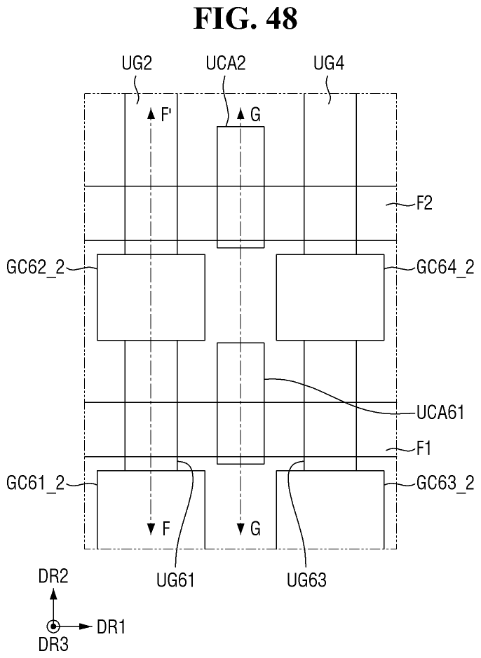

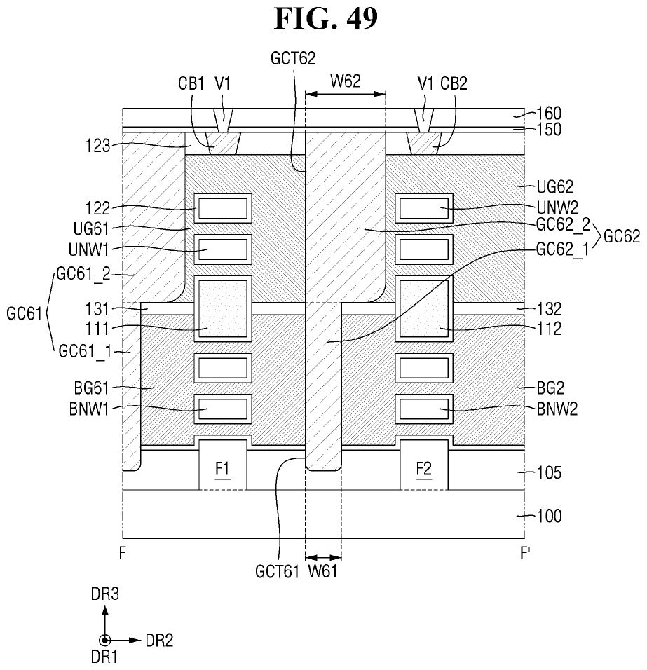

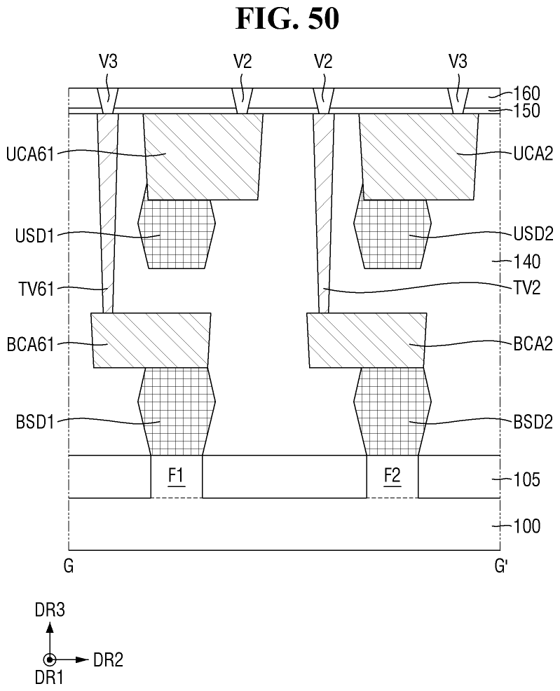

FIG. 46 is a layout view illustrating a semiconductor device, according to some embodiments of the present disclosure. FIG. 47 is a layout view illustrating a bottom structure of a semiconductor device, according to some embodiments of the present disclosure. FIG. 48 is a layout view illustrating an upper structure of a semiconductor device, according to some embodiments of the present disclosure. FIG. 49 is a cross-sectional view taken along line F-F′ of each of FIGS. 46 to 48. FIG. 50 is a cross-sectional view taken along line G-G′ of each of FIGS. 46 to 48.

Referring to FIGS. 46 to 50, in the semiconductor device, according to some embodiments of the present disclosure, a first gate cut GC61 may be disposed on a first side of a first bottom gate electrode BG61, and a second gate cut GC62 may be disposed on a second side of the first bottom gate electrode BG61, which is opposed to the first side of the first bottom gate electrode BG61 in the second horizontal direction DR2. A third gate cut GC63 may be disposed on a first side of the third bottom gate electrode BG63, and a fourth gate cut GC64 may be disposed on a second side of the third bottom gate electrode BG63, which is opposed to the first side of the third bottom gate electrode BG63 in the second horizontal direction DR2.

For example, the second gate cut GC62 may include a first portion GC62_1 and a second portion GC62_2 disposed on the first portion GC62_1. The first portion GC62_1 of the second gate cut GC62 may be disposed inside a first gate cut trench GTC61. The second portion GC62_2 of the second gate cut GC62 may be disposed inside a second gate cut trench GTC62. A width of the second gate cut trench GTC62 may be greater than that of the first gate cut trench GTC61 in the second horizontal direction DR2.

A first side of the first portion GC62_1 of the second gate cut GC62 may be in contact with the first bottom gate electrode BG61. A second side of the first portion GC62_1 of the second gate cut GC62, which is opposed to the first side of the first portion GC62_1 of the second gate cut GC62 in the second horizontal direction DR2, may be in contact with the second bottom gate electrode BG2. For example, a first side of the second portion GC62_2 of the second gate cut GC62 may be in contact with the first upper gate electrode UG61. The second side of the second portion GC62_2 of the second gate cut GC62, which is opposed to the first side of the second portion GC62_2 of the second gate cut GC62 in the second horizontal direction DR2, may be in contact with the second upper gate electrode UG2.

In some embodiments, the first side of the first portion GC62_1 of the second gate cut GC62 and the first side of the second portion GC62_2 of the second gate cut GC62 may have a continuous inclined profile. The second side of the first portion GC62_1 of the second gate cut GC62 may be formed to be closer to the second isolation layer 112 than the second side of the second portion GC62_2 of the second gate cut GC62. That is, a width W62 of the second portion GC62_2 of the second gate cut GC62 in the second horizontal direction DR2 may be greater than a width W61 of the first portion GC62_1 of the second gate cut GC62 in the second horizontal direction DR2.

The first gate cut GC61 may include a first portion GC61_1 and a second portion GC61_2 disposed on the first portion GC61_1. The first gate cut GC61 may have the same structure as that of the second gate cut GC62. For example, one side of the second portion GC61_2 of the first gate cut GC61, which faces the plurality of first upper nanosheets UNW1, may be formed to be closer to the first isolation layer 111 than one side of the first portion GC61_1 of the first gate cut GC61, which faces the plurality of first bottom nanosheets BNW1.

The third gate cut GC63 may include a first portion GC63_1 and a second portion GC63_2 disposed on the first portion GC63_1. The third gate cut GC63 may have the same structure as that of the first gate cut GC61. The fourth gate cut GC64 may include a first portion GC64_1 and a second portion GC64_2, which are disposed on the first portion GC64_1. The fourth gate cut GC64 may have the same structure as that of the second gate cut GC62.

A first bottom source/drain contact BCA61 may be connected to the first bottom source/drain region BSD1. The first bottom source/drain contact BCA1 may be extended in a direction opposite to the second horizontal direction DR2 toward the first gate cut GC61. At least a portion of the first bottom source/drain contact BCA1 may be disposed on the field insulating layer 105. The first upper source/drain contact UCA61 may be connected to the first upper source/drain region USD1. The first upper source/drain contact UCA61 may be extended in the second horizontal direction DR2 toward the second gate cut GC62. At least a portion of the first upper source/drain contact UCA61 may be disposed on the field insulating layer 105.

A first through via TV61 may be connected to the first bottom source/drain contact BCA61 by passing through the first interlayer insulating layer 140 in the vertical direction DR3. The first through via TV61 may be disposed on the field insulating layer 105. The first through via TV61 may overlap each of the second portion GC61_2 of the first gate cut GC61 and the second portion GC63_2 of the third gate cut GC63 in the first horizontal direction DR1. However, the first through via TV61 does not overlap each of the first portion GC61_1 of the first gate cut GC61 and the first portion GC63_1 of the third gate cut GC63 in the first horizontal direction DR1. Further, the first through via TV61 does not overlap each of the first upper gate electrode UG61 and the third upper gate electrode UG63 in the first horizontal direction DR1.

Although the embodiments according to the present disclosure have been described with reference to the accompanying drawings, the present disclosure can be manufactured in various forms without being limited to the above-described embodiments, and the person with ordinary skill in the art to which the present disclosure pertains can understand that the present disclosure can be embodied in other specific forms without departing from technical spirits and essential characteristics of the present disclosure. Thus, the above embodiments are to be considered in all respects as illustrative and not restrictive.

What is claimed is:

1. A semiconductor device, comprising:
a first active pattern extended in a first horizontal direction on a substrate;
a second active pattern extended in the first horizontal direction on the substrate, the second active pattern being spaced apart from the first active pattern in a second horizontal direction different from the first horizontal direction;
a first bottom gate electrode extended in the second horizontal direction on the first active pattern;
a first upper gate electrode extended in the second horizontal direction on the first bottom gate electrode, the first upper gate electrode being spaced apart from the first bottom gate electrode in a vertical direction;
a second bottom gate electrode extended in the second horizontal direction on the second active pattern, the second bottom gate electrode being spaced apart from the first bottom gate electrode in the second horizontal direction;
a second upper gate electrode extended in the second horizontal direction on the second bottom gate electrode, the second upper gate electrode being spaced apart from the second bottom gate electrode in the vertical direction, the second upper gate electrode being spaced apart from the first upper gate electrode in the second horizontal direction; and
a first gate cut comprising a first portion isolating the first bottom gate electrode from the second bottom gate electrode and a second portion isolating the first upper gate electrode from the second upper gate electrode,
wherein a width in the second horizontal direction of the second portion of the first gate cut exceeds a width in the second horizontal direction of the first portion of the first gate cut, and
wherein the second portion of the first gate cut overlaps at least one of the first bottom gate electrode and the second bottom gate electrode in the vertical direction.

2. The semiconductor device of claim 1, further comprising:
a plurality of first bottom nanosheets stacked in the vertical direction on the first active pattern, the plurality of first bottom nanosheets being spaced apart from each other in the vertical direction, the plurality of first bottom nanosheets being surrounded by the first bottom gate electrode;
a plurality of first upper nanosheets stacked in the vertical direction on the plurality of first bottom nanosheets, the plurality of first upper nanosheets being spaced apart from each other in the vertical direction, the plurality of first upper nanosheets being surrounded by the first upper gate electrode;
a plurality of second bottom nanosheets stacked in the vertical direction on the second active pattern, the plurality of second bottom nanosheets being spaced apart from each other in the vertical direction, the plurality of second bottom nanosheets being surrounded by the second bottom gate electrode; and
a plurality of second upper nanosheets stacked in the vertical direction on the plurality of second bottom nanosheets, the plurality of second upper nanosheets being spaced apart from each other in the vertical direction, the plurality of second upper nanosheets being surrounded by the second upper gate electrode.

3. The semiconductor device of claim 2, further comprising:
a first isolation layer disposed between the plurality of first bottom nanosheets and the plurality of first upper nanosheets; and
a second isolation layer disposed between the plurality of second bottom nanosheets and the plurality of second upper nanosheets.

4. The semiconductor device of claim 2, wherein the second portion of the first gate cut is in contact with each of the plurality of first upper nanosheets and the plurality of second upper nanosheets.

5. The semiconductor device of claim 1, further comprising:
a first gate isolation layer disposed between the first bottom gate electrode and the first upper gate electrode; and
a second gate isolation layer disposed between the second bottom gate electrode and the second upper gate electrode,
wherein at least a portion of a lower surface of the second portion of the first gate cut is in contact with the first gate isolation layer and the second gate isolation layer.

6. The semiconductor device of claim 1, further comprising:
a first bottom source/drain region disposed on a first side of the second bottom gate electrode on the second active pattern;
an interlayer insulating layer on the first bottom source/drain region;
a first bottom source/drain contact disposed inside the interlayer insulating layer and coupled to the first bottom source/drain region; and
a first through via coupled to the first bottom source/drain contact by passing through the interlayer insulating layer in the vertical direction, the first through via being overlapped with the second portion of the first gate cut in the first horizontal direction.

7. The semiconductor device of claim 6, further comprising:
a second bottom source/drain region disposed on a first side of the first bottom gate electrode on the first active pattern;
a second bottom source/drain contact disposed inside the interlayer insulating layer and coupled to the second bottom source/drain region; and
a second through via coupled to the second bottom source/drain contact by passing through the interlayer insulating layer in the vertical direction, the second through via being overlapped with the second portion of the first gate cut in the first horizontal direction.

8. The semiconductor device of claim 6, further comprising:
a second gate cut disposed on a second side of the first bottom gate electrode, the second side of the first bottom gate electrode being opposed in the second horizontal direction to the first side of the first bottom gate electrode, the second gate cut comprising a third portion in contact with the first bottom gate electrode and a fourth portion in contact with the first upper gate electrode;
a second bottom source/drain region disposed on a third side of the first bottom gate electrode on the first active pattern;
a second bottom source/drain contact disposed in the interlayer insulating layer and coupled to the second bottom source/drain region; and
a second through via coupled to the second bottom source/drain region by passing through the interlayer insulating layer in the vertical direction, the second through via being overlapped with the fourth portion of the second gate cut in the first horizontal direction.

9. The semiconductor device of claim 1, wherein a lower surface of the second portion of the first gate cut is in contact with each of the first bottom gate electrode and the second bottom gate electrode.

10. The semiconductor device of claim 1, wherein a first material of the first portion of the first gate cut is different from a second material of the second portion of the first gate cut.

11. The semiconductor device of claim 10, wherein an upper surface of the first portion of the first gate cut is in contact with a lower surface of the second portion of the first gate cut.

12. The semiconductor device of claim 10, wherein the second portion of the first gate cut surrounds sidewalls of the first portion of the first gate cut between the first upper gate electrode and the second upper gate electrode.

13. The semiconductor device of claim 1, wherein a first sidewall of the first portion of the first gate cut, which is in contact with the first bottom gate electrode, has an inclined profile with respect to a second sidewall of the second portion of the first gate cut, which is in contact with the first upper gate electrode.

14. A semiconductor device, comprising:
a first active pattern extended in a first horizontal direction on a substrate;
a second active pattern extended in the first horizontal direction on the substrate, the second active pattern being spaced apart from the first active pattern in a second horizontal direction different from the first horizontal direction;
a first bottom gate electrode extended in the second horizontal direction on the first active pattern;
a first upper gate electrode extended in the second horizontal direction on the first bottom gate electrode, the first upper gate electrode being spaced apart from the first bottom gate electrode in a vertical direction;
a second bottom gate electrode extended in the second horizontal direction on the second active pattern, the second bottom gate electrode being spaced apart from the first bottom gate electrode in the second horizontal direction;
a second upper gate electrode extended in the second horizontal direction on the second bottom gate electrode, the second upper gate electrode being spaced apart from the second bottom gate electrode in the vertical direction, the second upper gate electrode being spaced apart from the first upper gate electrode in the second horizontal direction;
a first bottom source/drain region disposed on one side of the first bottom gate electrode on the first active pattern;
an interlayer insulating layer on the first bottom source/drain region;
a first bottom source/drain contact disposed inside the interlayer insulating layer and coupled to the first bottom source/drain region; and
a first through via coupled to the first bottom source/drain contact by passing through the interlayer insulating layer in the vertical direction, the first through via being non-overlapped with the first upper gate electrode in the first horizontal direction,
wherein a pitch in the second horizontal direction between the first upper gate electrode and the second upper gate electrode exceeds a pitch in the second horizontal direction between the first bottom gate electrode and the second bottom gate electrode.

15. The semiconductor device of claim 14, further comprising:
a gate cut comprising a first portion isolating the first bottom gate electrode from the second bottom gate electrode and a second portion isolating the first upper gate electrode from the second upper gate electrode,
wherein a width in the second horizontal direction of the second portion of the gate cut exceeds a width in the second horizontal direction of the first portion of the gate cut, and
wherein the second portion of the gate cut overlaps at least one of the first bottom gate electrode and the second bottom gate electrode in the vertical direction.

16. The semiconductor device of claim 15, further comprising:
a first gate isolation layer disposed between the first bottom gate electrode and the first upper gate electrode; and
a second gate isolation layer disposed between the second bottom gate electrode and the second upper gate electrode,
wherein at least a portion of a lower surface of the second portion of the gate cut is in contact with the first gate isolation layer and the second gate isolation layer.

17. The semiconductor device of claim 15, wherein a lower surface of the second portion of the gate cut is in contact with each of the first bottom gate electrode and the second bottom gate electrode.

18. The semiconductor device of claim 15, wherein a first material of the first portion of the gate cut is different from a second material of the second portion of the gate cut.

19. The semiconductor device of claim 14, further comprising:
a second bottom source/drain region disposed on one side of the second bottom gate electrode on the second active pattern; and
a second through via coupled to the second bottom source/drain region by passing through the interlayer insulating layer in the vertical direction, the second through via being non-overlapped with the second upper gate electrode in the first horizontal direction.

20. A semiconductor device, comprising:
a first active pattern extended in a first horizontal direction on a substrate;
a second active pattern extended in the first horizontal direction on the substrate, the second active pattern being spaced apart from the first active pattern in a second horizontal direction different from the first horizontal direction;
a plurality of first bottom nanosheets stacked spaced apart from each other in a vertical direction on the first active pattern;
a plurality of first upper nanosheets stacked spaced apart from each other in the vertical direction on the plurality of first bottom nanosheets;
a plurality of second bottom nanosheets stacked spaced apart from each other in the vertical direction on the second active pattern;
a plurality of second upper nanosheets stacked spaced apart from each other in the vertical direction on the plurality of second bottom nanosheets;
a first bottom gate electrode extended in the second horizontal direction on the first active pattern, the first bottom gate electrode surrounding the plurality of first bottom nanosheets;
a first upper gate electrode extended in the second horizontal direction on the first bottom gate electrode, the first upper gate electrode being spaced apart from the first bottom gate electrode in the vertical direction, the first upper gate electrode surrounding the plurality of first upper nanosheets;
a second bottom gate electrode extended in the second horizontal direction on the second active pattern, the second bottom gate electrode being spaced apart from the first bottom gate electrode in the second horizontal direction, the second bottom gate electrode surrounding the plurality of second bottom nanosheets;
a second upper gate electrode extended in the second horizontal direction on the second bottom gate electrode, the second upper gate electrode being spaced apart from the second bottom gate electrode in the vertical direction, the second upper gate electrode being spaced apart from the first upper gate electrode in the second horizontal direction, the second upper gate electrode surrounding the plurality of second upper nanosheets;
a gate cut including a first portion isolating the first bottom gate electrode from the second bottom gate electrode and a second portion isolating the first upper gate electrode from the second upper gate electrode;
a bottom source/drain region disposed on one side of the first bottom gate electrode on the first active pattern;
an interlayer insulating layer on the bottom source/drain region;
a bottom source/drain contact disposed inside the interlayer insulating layer and coupled to the bottom source/drain region; and
a through via coupled to the bottom source/drain contact by passing through the interlayer insulating layer in the vertical direction, the through via being overlapped with the second portion of the gate cut in the first horizontal direction,
wherein a width in the second horizontal direction of the second portion of the gate cut exceeds a width in the second horizontal direction of the first portion of the gate cut.
